(19) United States
(12) Patent Application Publication
(10) Pub. No.: US 2020/0013835 A1
(43) Pub. Date: Jan. 9, 2020

(54) ORGANIC ELECTROLUMINESCENT DISPLAY DEVICE, PHASE DIFFERENCE FILM, AND CIRCULARLY POLARIZING PLATE

(71) Applicant: FUJIFILM Corporation, Tokyo (JP)

(72) Inventors: Ayako MURAMATSU, Kanagawa (JP); Kunihiro ATSUMI, Kanagawa (JP); Ryo SATAKE, Kanagawa (JP); Mayumi NOJIRI, Kanagawa (JP)

(73) Assignee: FUJIFILM Corporation, Tokyo (JP)

(21) Appl. No.: 16/575,975

(22) Filed: Sep. 19, 2019

Related U.S. Application Data
(63) Continuation of application No. PCT/JP2018/010841, filed on Mar. 19, 2018.

(30) Foreign Application Priority Data
Mar. 23, 2017 (JP) 2017-057173
Dec. 25, 2017 (JP) 2017-247753

(51) Int. Cl. H01L 27/32; H01L 51/52; G02B 5/30

(52) U.S. Cl. CPC H01L 27/3232; G02B 5/3016; H01L 51/5293

(57) ABSTRACT

The present invention provides an organic electroluminescent display device in which reflection of external light is suppressed and a change in tint in a case of being viewed in an oblique direction is further suppressed, a phase difference film, and a circular polarization plate. This organic electroluminescent display device according to the present invention includes an organic electroluminescence display panel and a circular polarization plate arranged on the organic electroluminescence display panel, in which the circular polarization plate includes a polarizer and a phase difference film, the phase difference film includes a positive A-plate and a positive C-plate, and the positive A-plate and the positive C-plate satisfy prescribed requirements.

### CROSS-REFERENCE TO RELATED APPLICATIONS

This application is a Continuation of PCT International Application No. PCT/JP2018/010841 filed on Mar. 19, 2018, which claims priority under 35 U.S.C. § 119(a) to Japanese Patent Application No. 2017-057173 filed on Mar. 23, 2017 and Japanese Patent Application No. 2017-247753 filed on Dec. 25, 2017. Each of the above applications is hereby expressly incorporated by reference, in its entirety, into the present application.

### BACKGROUND OF THE INVENTION

### 1. Field of the Invention

The present invention relates to an organic electroluminescent display device, a phase difference film, and a circularly polarizing plate.

### 2. Description of the Related Art

Conventionally, in order to suppress adverse effects of reflection of external light, a circularly polarizing plate has been used in an organic electroluminescent (EL) display device. As a circularly polarizing plate, for example, as described in JP2015-200861A, an aspect in which a positive A-plate and a positive C-plate are combined is disclosed.

### SUMMARY OF THE INVENTION

On the other hand, in recent years, in a display device typified by an organic EL display device, further improvement in viewing angle characteristics has been required. More specifically, in a display device including a circularly polarizing plate, it is required to further reduce reflection of external light.

In addition, when the display device is viewed in an oblique direction, it is also required that a change in tint (reflection tint) is small in the case where the organic EL display device is viewed while changing the azimuthal angle. That is, it is required that a change in tint in the case of being viewed in the oblique direction is further suppressed.

The present inventors have examined the characteristics of the display device including the circularly polarizing plate described JP2015-200861A and have found that suppression of reflection of external light and suppression of a change in tint in the case of being viewed in an oblique direction do not reach the recently required level and further improvement is required.

The present invention is made in consideration of the above circumstances and an object thereof is to provide an organic electroluminescent display device in which reflection of external light is suppressed and a change in tint in a case of being viewed in an oblique direction is further suppressed.

Another object of the present invention is to provide a phase difference film and a circularly polarizing plate in which reflection of external light is suppressed and a change in tint in a case of being viewed in an oblique direction is further suppressed.

As a result of intensive investigations on problems in the related art, the present inventors have found that the above problems can be solved by using a phase difference film satisfying predetermined requirements.

That is, the present inventors have found that the above problems can be solved by adopting the following configurations.

(1) An organic electroluminescent display device comprising: an organic electroluminescent display panel; and a circularly polarizing plate arranged on the organic electroluminescent display panel,

in which the circularly polarizing plate includes a polarizer and a phase difference film,

the phase difference film includes a positive A-plate and a positive C-plate,

the positive A-plate exhibits reverse wavelength dispersibility,

the positive A-plate satisfies a following requirement 1,

the positive A-plate and the positive C-plate satisfy a following requirement 2,

0.65≤ReA(450)/ReA(550)≤0.78, and Requirement 1:

{ReA(450)/ReA(550)−0.10}≤RthC(450)/RthC(550)/≤{ReA(450)/ReA(550)+0.10}, Requirement 2:

ReA(450) and ReA(550) represent in-plane retardations of the positive A-plate at wavelengths 450 nm and 550 nm, respectively, and

RthC(450) and RthC(550) represent retardations of the positive C-plate in a thickness direction at wavelengths 450 nm and 550 nm, respectively.

(2) The organic electroluminescent display device according to (1), in which the positive A-plate is formed by using a liquid crystal compound having a polymerizable group, and

the liquid crystal compound is a compound represented by Formula (I) described later.

(3) The organic electroluminescent display device according to (2), in which at least one of A¹ or A² is a cycloalkylene ring having 6 or more carbon atoms.

(4) The organic electroluminescent display device according to any one of (1) to (3), in which the positive A-plate satisfies a following requirement 1A.

0.68≤ReA(450)/ReA(550)≤0.76 Requirement 1A:

(5) The organic electroluminescent display device according to any one of (1) to (4), in which the positive A-plate and the positive C-plate satisfy a following requirement 2A.

{ReA(450)/ReA(550)−0.06}≤RthC(450)/RthC(550)/≤{ReA(450)/ReA(550)+0.06} Requirement 2:

(6) The organic electroluminescent display device according to any one of (1) to (5), in which ReA(550) of the positive A-plate is 100 to 180 nm.

(7) The organic electroluminescent display device according to any one of (1) to (6), in which the positive C-plate exhibits reverse wavelength dispersibility.

(8) A phase difference film comprising: a positive A-plate; and a positive C-plate,

in which the positive A-plate exhibits reverse wavelength dispersibility,

the positive A-plate satisfies a following requirement 1,

the positive A-plate and the positive C-plate satisfy a following requirement 2,

0.65≤ReA(450)/ReA(550)≤0.78, and Requirement 1:

{ReA(450)/ReA(550)−0.10}≤RthC(450)/RthC(550)/≤{ReA(450)/ReA(550)+0.10}, Requirement 2:

ReA(450) and ReA(550) represent in-plane retardations of the positive A-plate at wavelengths 450 nm and 550 nm, respectively, and

RthC(450) and RthC(550) represent retardations of the positive C-plate in a thickness direction at wavelengths 450 nm and 550 nm, respectively.

(9) The phase difference film according to (8), in which the positive A-plate is formed by using a liquid crystal compound having a polymerizable group, and

the liquid crystal compound is a compound represented by Formula (I) described later.

(10) The phase difference film according to (9), in which at least one of A¹ or A² is a cycloalkylene ring having 6 or more carbon atoms.

(11) The phase difference film according to any one of (8) to (10), in which the positive A-plate satisfies a following requirement 1A.

0.68≤ReA(450)/ReA(550)≤0.76, and Requirement 1:

(12) The phase difference film according to any one of (8) to (11), in which the positive A-plate and the positive C-plate satisfy a following requirement 2A.

{ReA(450)/ReA(550)−0.06}≤RthC(450)/RthC(550)/≤{ReA(450)/ReA(550)+0.06}, Requirement 2:

(13) The phase difference film according to any one of (8) to (12), in which ReA(550) of the positive A-plate is 100 to 180 nm.

(14) The phase difference film according to any one of (8) to (13), in which the positive C-plate exhibits reverse wavelength dispersibility.

(15) A circularly polarizing plate comprising: a polarizer; and the phase difference film according to any one of (8) to (14).

According to the present invention, it is possible to provide an organic electroluminescent display device in which reflection of external light is suppressed and a change in tint in a case of being viewed in an oblique direction is further suppressed.

Further, according to the present invention, it is possible to provide a phase difference film and a circularly polarizing plate in which reflection of external light is suppressed and a change in tint in a case of being viewed in an oblique direction is further suppressed.

### BRIEF DESCRIPTION OF THE DRAWINGS

FIG. 1 is a cross-sectional view of a phase difference film according to the present invention.

FIG. 2 is a cross-sectional view of a circularly polarizing plate of the present invention.

FIG. 3 is a view showing a relationship between an absorption axis of a polarizer and an in-plane slow axis of a positive A-plate in the circularly polarizing plate of the present invention.

FIG. 4 is a cross-sectional view of an organic EL display device according to the present invention.

### DESCRIPTION OF THE PREFERRED EMBODIMENTS

Hereinafter, the present invention will be described in detail. In the present specification, the numerical value range expressed by the term “to” means that the numerical values described before and after “to” are included as a lower limit and an upper limit, respectively. First, the terms used in the present specification will be described.

In the present invention, Re(λ) and Rth(λ) respectively represent an in-plane retardation and a retardation in a thickness direction at a wavelength λ. For example, Re(450) represents an in-plane retardation at a wavelength of 450 nm. Unless otherwise specified, the wavelength λ is 550 nm.

In addition, ReA(λ) and RthA(λ) respectively represent the in-plane retardation and the retardation in the thickness direction of the positive A-plate at a wavelength of λ nm. Further, ReC(λ) and RthC(λ) respectively represent the in-plane retardation and the retardation in the thickness direction of the positive C-plate at a wavelength of λ nm.

In the present invention. Re(λ) and Rth(λ) are values measured at wavelength λ in AxoScan OPMF-1 (manufactured by Opto Science. Inc.). By inputting the average refractive index ((nx+ny+nz)/3) and the film thickness (d (μm)) to AxoScan, the following expressions can be calculated.

Slow axis direction (°)

Re(λ)=R0(λ)

Rth(λ)=((nx+ny)/2−nz)×d

R0(λ) is expressed as a numerical value calculated by AxoScan OPMF-1 but means Re(λ).

In the present specification, the refractive indices nx, ny, and nz are measured using an Abbe refractometer (NAR-4T, manufactured by Atago Co., Ltd.), and a sodium lamp (λ=589 nm) is used as a light source. In addition, in the case where the wavelength dependence is measured, the wavelength dependence can be measured using a combination of a multi-wavelength Abbe refractometer DR-M2 (manufactured by Atago Co., Ltd.) and an interference filter.

In addition, as the refractive index, values described in “Polymer Handbook” (John Wiley&Sons, Inc.) and catalogs of various optical films can also be used. The values of average refractive index of major optical films are as follows: cellulose acylate (1.48), cycloolefin polymer (1.52), polycarbonate (1.59), polymethyl methacrylate (1.49), and polystyrene (1.59).

In the present specification, the Nz factor is a value obtained from Nz=(nx−nz)/(nx−ny).

In the present specification, the term “visible light” refers to light in a wavelength range of 380 to 800 nm.

In the present specification, an angle (for example, an angle of “90°” or the like) and an angular relationship (for example, “orthogonal”, “parallel”, and “crossing at 45°”) include the margin of allowable error in the technical field to which the present invention belongs. For example, the allowable error means that the margin of the error is within a precise angle ±100. A difference between an actual angle and the precise angle is preferably 5° or less and more preferably 3° or less.

In the present specification, the definition of A-plate is as follows.

There are two kinds of A-plates: a positive A-plate and a negative A-plate, and when the refractive index in the slow axis direction (the direction in which the refractive index in the plane is maximum) in the film plane is nx, the refractive index orthogonal to the in-plane slow axis in the plane is ny, and the refractive index in the thickness direction is nz, the positive A-plate satisfies the relationship of Expression (A1), and the negative A-plate satisfies the relationship of Expression (A2). The positive A-plate has a positive Rth value and the negative A-plate has a negative Rth value.

nx>ny≅nz Expression (A1)

ny<nx≅nz Expression (A2)

The expression “≅” includes not only a case in which both arc completely the same but also a case in which both are substantially the same. Regarding the expression “substantially the same”, for example, “ny≅nz” includes a case in which (ny−nz)×d (wherein d represents a film thickness) is −10 to 10 nm and preferably −5 to 5 nm, and “nx≅nz” includes a case in which (nx−nz)×d is −10 to 10 nm and preferably −5 to 5 nm.

There are two kinds of C-plates: a positive C-plate and a negative C-plate. The positive C-plate satisfies the relationship of Expression (C1), and the negative C-plate satisfies the relationship of Expression (C2). Rth of the positive C-plate shows a negative value and Rth of the negative C-plate shows a positive value.

nz>nx≅ny Expression (C1)

nz<nx≅ny Expression (C2)

The expression “≅” includes not only a case in which both are completely the same but also a case in which both are substantially the same. Regarding the expression “substantially the same”, for example, “nx≅ny” includes a case in which (nx−ny)×d (wherein d represents a film thickness) is 0 to 10 nm, and preferably 0 to 5 nm.

In the present specification, an “absorption axis” of a polarizer means a direction in which absorbance is maximized. A “transmission axis” means a direction in which an angle with respect to the “absorption axis” is 90°.

In the present specification, a “slow axis” of a positive A-plate means a direction in which a refractive index is maximized in a plane.

The bonding direction of a divalent group (for example, —O—CO—) described in the present specification is not particularly limited, and for example, in a case where D¹ in Formula (I) described later is —O—CO—, assuming that the position bonded to the Ar side is *1 and the position bonded to the G¹ side is *2, D¹ may be *1-O—CO-*2 or *1-CO—O-*2.

Hereinafter, an organic electroluminescent display device (organic EL display device), a phase difference film, and a circularly polarizing plate according to embodiments of the present invention will be described with drawings.

In the following, the phase difference film, the circularly polarizing plate, and the organic EL display device will be described in this order.

<Phase Difference Film>

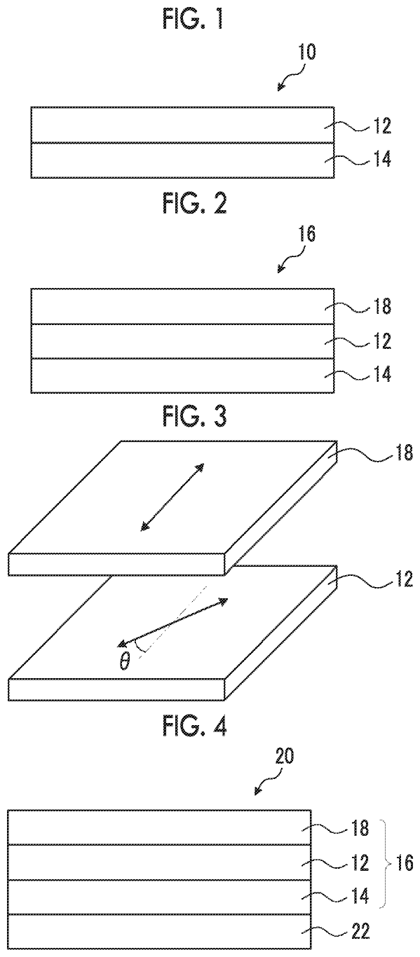

A phase difference film according to an embodiment of the present invention will be described with the drawings. FIG. 1 is a cross-sectional view showing a phase difference film according to an embodiment of the present invention. The drawing in the present invention is a schematic view and the relationship and positional relationship between the thicknesses of each layer do not necessarily coincide with the actual ones.

A phase difference film 10 includes a positive A-plate 12 and a positive C-plate 14. It is preferable that the positive A-plate 12 and the positive C-plate 14 respectively has a single layer structure.

Hereinafter, each member included in the phase difference film 10 will be described in detail.

(Positive A-Plate)

The positive A-plate satisfies the following requirement 1.

0.65≤ReA(450)/ReA(550)≤0.78, and Requirement 1:

ReA(450) and ReA(550) represent in-plane retardations of the positive A-plate at wavelengths 450 nm and 550 nm, respectively.

In the requirement 1, a range of a ratio of ReA(450), which is the in-plane retardation of the positive A-plate at a wavelength of 450 nm, with respect to ReA(550), which is the in-plane retardation of the positive A-plate at a wavelength of 550 nm, is shown. In the related art, the ReA(450)/ReA(550) is 0.80 or more in many cases. In the present invention, it is found that by adjusting the ReA(450)/ReA(550) to be in the following range, the desired effect can be obtained.

In the relationship, from the viewpoint of further suppressing reflection of external light and/or a change in tint of an organic EL display device in a case of being viewed in an oblique direction (hereinafter, simply referred to as “from the viewpoint that the effect of the present invention is more excellent”), it is preferable that the positive A-plate satisfies the following requirement 1A.

0.68≤ReA(450)/ReA(550)≤0.76, and Requirement 1:

The positive A-plate exhibits reverse wavelength dispersibility. The reverse wavelength dispersibility is preferably exhibited in the visible light range.

The positive A-plate exhibiting forward wavelength dispersibility means that the in-plane retardation of the positive A-plate exhibits forward wavelength dispersibility. That is, this means that as the measurement wavelength increases, the in-plane retardation of the positive A-plate decreases. In other words, the ReA(450)/ReA(550), ReA(500)/ReA(550), ReA(600)/ReA(550), and ReA(650)/ReA(550) described later satisfy the following relationship X.

{ReA(450)/ReA(550)}<{ReA(500)/ReA(550)}<{ReA(600)/ReA(550)}<{ReA(650)/ReA(550)} Relationship X:

In order to set the in-plane retardation of the positive A-plate to appropriately exhibit reverse wavelength dispersibility, specifically, the ReA(500)/ReA(550) of the positive A-plate is preferably 0.83 to 0.99, and more preferably 0.89 to 0.97. The ReA(500)/ReA(550) represents a ratio of ReA(500), which is the in-plane retardation of the positive A-plate at a wavelength of 500 nm, with respect to ReA(550), which is the in-plane retardation of the positive A-plate at a wavelength of 550 nm.

In addition, the ReA(600)/ReA(550) of the positive A-plate is preferably 1.01 to 1.12 and more preferably 1.01 to 1.08. The ReA(600)/ReA(550) represents a ratio of ReA(600), which is the in-plane retardation of the positive A-plate at a wavelength of 600 nm, with respect to ReA(550), which is the in-plane retardation of the positive A-plate at a wavelength of 550 nm.

Further, the ReA(650)/ReA(550) of the positive A-plate is preferably 1.03 to 1.16 and more preferably 1.04 to 1.10. The ReA(650)/ReA(550) represents a ratio of ReA(650), which is the in-plane retardation of the positive A-plate at a wavelength of 650 nm, with respect to ReA(550), which is the in-plane retardation of the positive A-plate at a wavelength of 550 nm.

The ReA(550), which is the in-plane retardation of the positive A-plate at a wavelength of 550 nm, is preferably 100 to 180 nm, more preferably 120 to 160 nm, even more preferably 130 to 150 nm, and particularly preferably 130 to 140 nm from the viewpoint that the effect of the present invention is more excellent.

The RthA(550), which is the retardation of the positive A-plate in the thickness direction at a wavelength of 550 nm is preferably 50 to 90 nm, more preferably 60 to 180 nm, even more preferably 65 to 75 nm, and particularly preferably 65 to 70 nm from the viewpoint that the effect of the present invention is more excellent.

The thickness of the positive A-plate is not particularly limited and is adjusted such that the in-plane retardation is set to be in a predetermined range. From the viewpoint of reducing the thickness of the phase difference film, the thickness is preferably 10 μm or less, more preferably 0.5 to 8.0 μm, and even more preferably 0.5 to 6.0 μm.

In the present specification, the thickness of the positive A-plate means the average thickness of the positive A-plate. The average thickness is obtained by measuring the thickness at 5 or more random points in the positive A-plate and arithmetically averaging those values.

It is preferable that the positive A-plate is a layer formed by using a liquid crystal compound. However, as long as predetermined characteristics such as the above-mentioned in-plane retardation are satisfied, the positive A-plate may be constituted of another material. For example, the positive A-plate may be formed by using a polymer film (particularly, a polymer film subjected to a stretching treatment).

Conventionally, a rigid flat type display panel has been mainly used as an organic electroluminescent display panel (organic EL display panel). However, in recent years, a foldable flexible organic EL display panel has been proposed. For a circularly polarizing plate used for such a flexible organic EL display panel, it is required that the circularly polarizing plate itself is excellent in flexibility. From this viewpoint, since the positive A-plate formed by using a liquid crystal compound is more flexible than a polymer film, the circularly polarizing plate can be suitably applied to a flexible organic EL display panel.

In addition, for the above reason, the positive C-plate described in detail later is also preferably a positive C-plate formed by using a liquid crystal compound.

That is, a phase difference film (or circularly polarizing plate) including a positive A-plate formed by using a liquid crystal compound and a positive C-plate formed by using a liquid crystal compound can be more suitably applied to a flexible organic EL display panel.

The kind of liquid crystal compound is not particularly limited but, liquid crystal compounds can be classified into a rod-like type (rod-like liquid crystal compound) and a disk-like type (disk-like liquid crystal compound, discotic liquid crystal compound) based on the shape thereof. Further, each kind includes a low molecular type and a high molecular type. A high molecule generally indicates a molecule having a polymerization degree of 100 or more (Masao Doi; Polymer Physics-Phase Transition Dynamics, 1992, IWANAMI SIHOTEN, PUBLISHERS, page 2). A mixture of two or more kinds of rod-like liquid crystal compounds, two or more kinds of disk-like liquid crystal compounds, or a rod-like liquid crystal compound and a disk-like liquid crystal compound may be used.

Since changes in temperature and humidity in optical properties can be made small, it is more preferable to form the positive A-plate using a liquid crystal compound (rod-like liquid crystal compound or disk-like liquid crystal compound) having a polymerizable group. The liquid crystal compound may be a mixed compound of two or more kinds. In this case, it is preferable that at least one has two or more polymerizable groups.

That is, it is preferable that the positive A-plate is a layer formed by fixing a liquid crystal compound (rod-like liquid crystal compound or disk-like liquid crystal compound) having a polymerizable group through polymerization or the like. In this case, after the layer is formed, the liquid crystal compound does not need to exhibit liquid crystallinity any longer.

The kind of the polymerizable group is not particularly limited and a polymerizable group capable of causing radical polymerization or cationic polymerization is preferable.

A known radically polymerizable group can be used as a radically polymerizable group, and an acryloyl group or a methacryloyl group is preferable.

As a cationically polymerizable group, a known cationically polymerizable group can be used, and specific examples thereof include an alicyclic ether group, a cyclic acetal group, a cyclic lactone group, a cyclic thioether group, a spiro ortho ester group, and a vinyloxy group. Among these, an alicyclic ether group or a vinyloxy group is preferable, and an epoxy group, an oxetanyl group, or a vinyloxy group is more preferable.

Examples of particularly preferable polymerizable groups include the following.

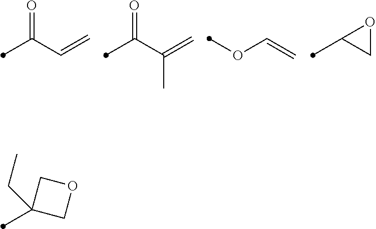

Among these, as the liquid crystal compound used in a case of forming the positive A-plate, a compound represented by Formula (I) is preferable.

L¹-SP¹-A¹-D³-G¹-D¹-Ar-D-G²-D⁴-A²-SP²-L² Formula (I)

In Formula (I), D¹, D², D³ and D⁴ each independently represent a single bond, —O—CO—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—O—CO—CR³R⁴—, —CR¹R²—CO—O—CR³R⁴—, —NR¹—CR²R³—, or —CO—NR¹—.

R¹, R², R³ and R⁴ each independently represent a hydrogen atom, a fluorine atom, or an alkyl group having 1 to 4 carbon atoms.

In addition, in Formula (I), G¹ and G² each independently represent a divalent alicyclic hydrocarbon group having 5 to 8 carbon atoms, and one or more —CH₂— groups constituting the alicyclic hydrocarbon group may be substituted by —O—, —S— or —NH—.

In addition, in Formula (I), A¹ and A² each independently represent a single bond, an aromatic ring having 6 or more carbon atoms or a cycloalkylene ring having 6 or more carbon atoms.

In addition, in Formula (I), SP¹ and SP² each independently represent a single bond, a linear or branched alkylene group having 1 to 14 carbon atoms, or a divalent linking group in which one or more —CH₂— groups constituting the linear or branched alkylene group having 1 to 14 carbon atoms are substituted by —O—, —S—, —NH—, —N(Q)-, or —CO—, and Q represents a polymerizable group.

In addition, in Formula (I), L¹ and L² each independently represent a monovalent organic group (for example, an alkyl group or a polymerizable group).

In a case where Ar is a group represented by Formula (Ar-1), Formula (Ar-2), Formula (Ar-4), or Formula (Ar-5) described later, at least one of L¹ or L² represents a polymerizable group. In addition, in a case where Ar is a group represented by Formula (Ar-3) described later, at least one of L¹ or L², or L or L⁴ in Formula (Ar-3) represents a polymerizable group.

In Formula (I), as the divalent alicyclic hydrocarbon group having 5 to 8 carbon atoms represented by G¹ and G², a 5-membered ring or a 6-membered ring is preferable. In addition, the alicyclic hydrocarbon group may be a saturated alicyclic hydrocarbon group or an unsaturated alicyclic hydrocarbon group, but a saturated alicyclic hydrocarbon group is preferable. As the divalent alicyclic hydrocarbon group represented by G¹ and G², for example, the description of paragraph 0078 of JP2012-021068A can be referred to, and the contents thereof are incorporated herein.

In Formula (I), examples of the aromatic ring having 6 or more carbon atoms represented by A¹ and A² include aromatic hydrocarbon rings such as a benzene ring, a naphthalene ring, an anthracene ring, and a phenanthroline ring; and aromatic heterocyclic rings such as a furan ring, a pyrrole ring, a thiophene ring, a pyridine ring, a thiazole ring, and a benzothiazole ring. Among these, a benzene ring (for example, a 1,4-phenyl group) is preferable.

Further, in Formula (I), examples of the cycloalkylene ring having 6 or more carbon atoms represented by A¹ and A² include a cyclohexane ring, and a cyclohexene ring. Among these, a cyclohexane ring (for example, a cyclohexane-1,4-diyl group) is preferable.

In Formula (I), as the linear or branched alkylene group having 1 to 14 carbon atoms represented by SP¹ and SP², a methylene group, an ethylene group, a propylene group or a butylene group is preferable.

In Formula (I), the polymerizable group represented by L¹ and L² is not particularly limited and a radical polymerizable group (radically polymerizable group) or a cationic polymerizable group (cationically polymerizable group) is preferable.

A preferable range of the radical polymerizable group is as described above.

On the other hand, in Formula (I), Ar represents any aromatic ring selected from the group consisting of groups represented by Formulae (Ar-1) to (Ar-5). In Formulae (Ar-1) to (Ar-5), *1 represents a bonding position to D¹ and *2 represents a bonding position to D².

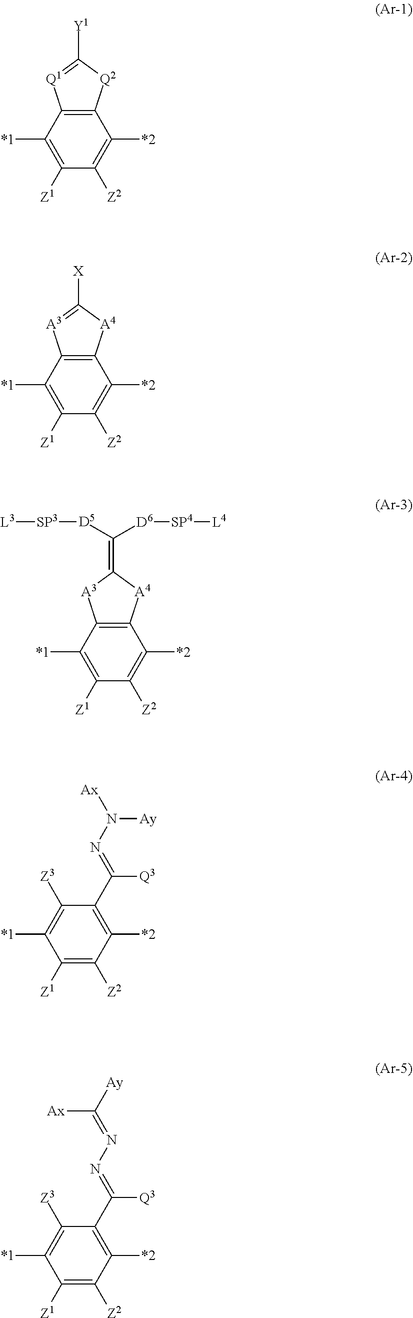

Here, in Formula (Ar-1), Q¹ represents N or CH, Q² represents —S—, —O—, or —N(R⁵)—, R⁵ represents a hydrogen atom or an alkyl group having 1 to 6 carbon atoms, and Y¹ represents an aromatic hydrocarbon group having 6 to 12 carbon atoms or an aromatic heterocyclic group having 3 to 12 carbon atoms, which may have a substituent.

Examples of the alkyl group having 1 to 6 carbon atoms represented by R⁵ include a methyl group, an ethyl group, a propyl group, an isopropyl group, an n-butyl group, an isobutyl group, a sec-butyl group, a tert-butyl group, an n-pentyl group, and an n-hexyl group.

Examples of the aromatic hydrocarbon group having 6 to 12 carbon atoms represented by Y¹ include aryl groups such as a phenyl group, a 2,6-diethylphenyl group, and a naphthyl group.

Examples of the aromatic heterocyclic group having 3 to 12 carbon atoms represented by Y¹ include heteroaryl groups such as a thienyl group, a thiazolyl group, a furyl group, a pyridyl group, and a benzofuryl group. The aromatic heterocyclic group also includes a group in which a benzene ring and an aromatic heterocyclic ring are condensed.

In addition, examples of the substituent which Y¹ may have an alkyl group, an alkoxy group, a nitro group, an alkylsulfonyl group, an alkyloxycarbonyl group, a cyano group, and a halogen atom.

As the alkyl group, for example, a linear, branched or cyclic alkyl group having 1 to 18 carbon atoms is preferable, an alkyl group having 1 to 8 carbon atoms (for example, a methyl group, an ethyl group, a propyl group, an isopropyl group, an n-butyl group, an isobutyl group, a sec-butyl group, a t-butyl group, and a cyclohexyl group) is more preferable, an alkyl group having 1 to 4 carbon atoms is even more preferable, and a methyl group or an ethyl group is particularly preferable.

As the alkoxy group, for example, an alkoxy group having 1 to 18 carbon atoms is preferable, an alkoxy group having 1 to 8 carbon atoms (for example, a methoxy group, an ethoxy group, an n-butoxy group, and a methoxyethoxy group) is more preferable, an alkoxy group having 1 to 4 carbon atoms is even more preferable, and a methoxy group or an ethoxy group is particularly preferable.

As the halogen atom, for example, a fluorine atom, a chlorine atom, a bromine atom, an iodine atom may be used and a fluorine atom or a chlorine atom is preferable.

In addition, in Formulae (Ar-1) to (Ar-5), Z¹, Z² and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a halogen atom, a cyano group, a nitro group, —NR⁶R⁷, or —SR⁸, R⁶ to R⁸ each independently represent a hydrogen atom or an alkyl group having 1 to 6 carbon atoms, and Z¹ and Z² may be bonded to each other to form a ring. The ring may be any of alicyclic, heterocyclic and aromatic rings, and is preferably an aromatic ring. In addition, the ring formed may be substituted by a substituent.

As the monovalent aliphatic hydrocarbon group having 1 to 20 carbon atoms, an alkyl group having 1 to 15 carbon atoms is preferable, an alkyl group having 1 to 8 carbon atoms is more preferable, a methyl group, an ethyl group, an isopropyl group, a tert-pentyl group (1,1-dimethylpropyl group), a tert-butyl group or 1,1-dimethyl-3,3-dimethyl-butyl group is even more preferable, and a methyl group, an ethyl group or a tert-butyl group is particularly preferable.

Examples of the monovalent alicyclic hydrocarbon group having 3 to 20 carbon atoms include monocyclic saturated hydrocarbon groups such as a cyclopropyl group, a cyclobutyl group, a cyclopentyl group, a cyclohexyl group, a cycloheptyl group, a cyclooctyl group, a cyclodecyl group, a methylcyclohexyl group, and an ethylcyclohexyl group; monocyclic unsaturated groups such as a cyclobutenyl group, a cyclopentenyl group, a cyclohexenyl group, a cycloheptenyl group, a cyclooctenyl group, a cyclodecenyl group, a cyclopentadienyl group, a cyclohexadienyl group, a cyclooctadienyl group, and a cyclodecadiene group; polycyclic saturated hydrocarbon groups such as a bicyclo[2.2.1]heptyl group, a bicyclo[2.2.2]octyl group, a tricyclo[5.2.1.0^{2,6}]decyl group, a tricyclo[3.3.1.1^{3,7}]decyl group, a tetracyclo[6.2.1.1^{3,6}.0^{2,7}]dodecyl group, and an adamantyl group.

Examples of the monovalent aromatic hydrocarbon group having 6 to 20 carbon atoms include a phenyl group, a 2,6-diethylphenyl group, a naphthyl group, and a biphenyl group, and an aryl group having 6 to 12 carbon atoms (particularly, a phenyl group) is preferable.

Examples of the halogen atom include a fluorine atom, a chlorine atom, a bromine atom, and an iodine atom, and a fluorine atom, a chlorine atom, or a bromine atom is preferable.

On the other hand, examples of the alkyl group having 1 to 6 carbon atoms represented by R⁶ to R⁸ include a methyl group, an ethyl group, a propyl group, an isopropyl group, an n-butyl group, an isobutyl group, a sec-butyl group, a tert-butyl group, an n-pentyl, and an n-hexyl group.

In addition, in Formulae (Ar-2) and (Ar-3), A³ and A⁴ each independently represent a group selected from the group consisting of —O—, —N(R⁹)—, —S—, and —CO—, and R⁹ represents a hydrogen atom or a substituent.

Examples of the substituent represented by R⁹ include the same substituents as the substituents which Y¹ may have in Formula (Ar-1).

In addition, in Formula (Ar-2), X represents a hydrogen atom or a non-metal atom of Groups 14 to 16 to which a substituent may be bonded.

Further, examples of the non-metal atom of Groups 14 to 16 represented by X include an oxygen atom, a sulfur atom, a nitrogen atom having a substituent, and a carbon atom having a substituent, and examples of the substituent include the same substituents as the substituents which Y¹ in Formula (Ar-1) may have.

In addition, in Formula (Ar-3), D⁵ and D⁶ each independently represent a single bond, —O—CO—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—O—CO—CR³R⁴—, —CR¹R²—CO—O—CR³R⁴—, —NR¹—CR²R³—, or —CO—NR¹—. R¹, R², R³, and R⁴ each independently represent a hydrogen atom, a fluorine atom, or an alkyl group having 1 to 4 carbon atoms.

In addition, in Formula (Ar-3), SP³ and SP⁴ each independently represent a single bond, an linear or branched alkylene group having 1 to 12 carbon atoms, or a divalent linking group in which one or more —CH₂— groups constituting the linear or branched alkylene group having 1 to 12 carbon atoms are substituted by —O—, —S—, —NH—, —N(Q)-, or —CO—, and Q represents a polymerizable group.

In addition, in Formula (Ar-3), L³ and L⁴ each independently represent a monovalent organic group (for example, an alkyl group or a polymerizable group), and as described above, at least one of L³ or L⁴, or L¹ or L² in Formula (I) represents a polymerizable group.

In addition, in Formulae (Ar-4) and (Ar-5), Ax represents an organic group having 2 to 30 carbon atoms, which has at least one aromatic ring selected from the group consisting of an aromatic hydrocarbon ring and an aromatic heterocyclic ring.

In addition, in Formulae (Ar-4) and (Ar-5), Ay represents a hydrogen atom, an alkyl group having 1 to 6 carbon atoms which may have a substituent, or an organic group having 2 to 30 carbon atoms, which has at least one aromatic ring selected from the group consisting of an aromatic hydrocarbon ring and an aromatic heterocyclic ring.

Here, the aromatic rings in Ax and Ay may respectively have a substituent, Ax and Ay may be bonded to form a ring.

In addition, Q³ represents a hydrogen atom or an alkyl group having 1 to 6 carbon atoms which may have a substituent.

Examples of Ax and Ay include ones described in paragraphs 0039 to 0095 of WO2014/010325A.

Examples of the alkyl group having 1 to 6 carbon atoms represented by Q³ include a methyl group, an ethyl group, a propyl group, an isopropyl group, an n-butyl group, an isobutyl group, a sec-butyl group, a tert-butyl group, and an n-pentyl group and an n-hexyl group. Examples of the substituent include the same substituents as the substituents which Y¹ may have in Formula (Ar-1).

Among these, from the viewpoint that the effect of the present invention is more excellent, at least one of A¹ or A² is preferably a cycloalkylene ring having 6 or more carbon atoms and one of A¹ and A² is more preferably a cycloalkylene ring having 6 or more carbon atoms.

The method of forming the positive A-plate is not particularly limited and known methods may be used.

Among these, from the viewpoint of easy control of in-plane retardation, a method of applying a positive A-plate forming composition (hereinafter, also simply referred to as “composition”) including a liquid crystal compound having a polymerizable group (hereinafter, also simply referred to as “polymerizable liquid crystal compound”) to form a coating film, subjecting the coating film to an alignment treatment to align the polymerizable liquid crystal compound, and subjecting the obtained coating film to a curing treatment (ultraviolet irradiation (photoirradiation treatment) or heating treatment) to obtain a positive A-plate is preferable.

Hereinafter, the procedures of the method will be described in detail.

First, a composition is applied to a support to form a coating film, and the coating film is subjected to an alignment treatment to align a polymerizable liquid crystal compound.

The composition used includes a polymerizable liquid crystal compound. The definition of the polymerizable liquid crystal compound is as described above.

Although the content of the polymerizable liquid crystal compound in the composition is not particularly limited, from the viewpoint of easy control of in-plane retardation of the positive A-plate, the content of the polymerizable liquid crystal compound is preferably 50% by mass or more, more preferably 70% by mass or more, and even more preferably 90% by mass or more with respect to the total solid content of the composition. The upper limit is not particularly limited and is 99% by mass or less in many cases.

The total solid content of the composition does not include a solvent.

The composition may include components other than the above-described polymerizable liquid crystal compound.

For example, the composition may contain a liquid crystal compound having no polymerizable group. Examples of the liquid crystal compound having no polymerizable group include liquid crystal compounds in which any of L¹ and L² in Formula (I) represents groups other than a polymerizable group.

In addition, the composition may include a polymerization initiator. A polymerization initiator to be used is selected according to the kind of polymerization reaction and examples thereof include a thermal polymerization initiator and a photopolymerization initiator. Examples of the photopolymerization initiator include α-carbonyl compounds, acyloin ethers, α-hydrocarbon-substituted aromatic acyloin compounds, polynuclear quinone compounds, and a combination of triarylimidazole diner and p-aminophenyl ketone.

The content of the polymerization initiator in the composition is preferably 0.01% to 20% by mass and more preferably 0.5% to 5% by mass with respect to the total solid content of the composition.

In addition, the composition may contain a polymerizable monomer.

The polymerizable monomer may be, for example, a radically polymerizable or cationically polymerizable compound. Among these, a polyfunctional radically polymerizable monomer is preferable. Further, as the polymerizable monomer, a copolymerizable monomer which is copolymerized with the liquid crystal compound having the above-mentioned polymerizable group is preferable. Examples of the polymerizable monomer include polymerizable monomers described in paragraphs 0018 to 0020 of JP2002-296423A.

The content of the polymerizable monomer in the composition is preferably 1% to 50% by mass and more preferably 2% to 30% by mass with respect to the total mass of the polymerizable liquid crystal compound.

Further, the composition may include a surfactant.

Examples of the surfactant include conventionally known compounds, and a fluorine-based compound is particularly preferable. Examples of the surfactant include the compounds described in paragraphs 0028 to 0056 of JP2001-330725A and the compounds described in paragraphs 0069 to 0126 of JP2003-295212.

Further, the composition may include a solvent. An organic solvent is preferably used as the solvent. Examples of the organic solvent include an amide (for example, N,N-dimethylformamide), a sulfoxide (for example, dimethyl sulfoxide), a heterocyclic compound (for example, pyridine), a hydrocarbon (for example, benzene or hexane), an alkyl halide (for example, chloroform or dichloromethane), an ester (for example, methyl acetate, ethyl acetate, or butyl acetate), a ketone (for example, acetone or methyl ethyl ketone), and an ether (for example, tetrahydrofuran or 1,2-dimethoxyethane). Two or more kinds of organic solvents may be used in combination.

Further, the composition may contain various alignment controlling agents such as a vertical alignment agent and a horizontal alignment agent. These alignment controlling agents are compounds capable of controlling the alignment of the liquid crystal compound horizontally or vertically on the interface side.

Further, the composition may include an adhesion improver, a plasticizer, a polymer and the like in addition to the above-mentioned components.

The support used is a member having a function as a base material for applying the composition. The support may be a temporary support which is peeled off after the composition is applied and cured.

As the support (temporary support), in addition to a plastic film, a glass substrate or the like may be used. Examples of materials constituting the plastic film include polyester resins such as polyethylene terephthalate (PET), polycarbonate resins, (meth)acrylic resins, epoxy resins, polyurethane resins, polyamide resins, polyolefin resins, cellulose derivatives, silicone resins, and polyvinyl alcohol (PVA).

The thickness of the support may be about 5 to 1000 μm and is preferably 10 to 250 μm and more preferably 15 to 90 μm.

If necessary, an alignment film may be arranged on the support.

The alignment film generally contains a polymer as a main component. Polymers for alignment films are described in many documents, and many commercial products are available. The polymer to be used is preferably polyvinyl alcohol, polyimide, or a derivative thereof.

The alignment film is preferably subjected to a known rubbing treatment.

The thickness of the alignment film is preferably 0.01 to 10 μm and more preferably 0.01 to 1 μm.

In addition, as the alignment film, a so-called photo alignment film may be used. The photo alignment film is a film formed by irradiating a photo alignment material with polarized light or non-polarized light. Examples of the photo alignment material include a polymer having an azobenzene group or a cinnamate group.

Examples of the method for applying the composition include known methods such as a curtain coating method, a dip coating method, a spin coating method, a printing coating method, a spray coating method, a slot coating method, a roll coating method, a slide coating method, a blade coating method, a gravure coating method, and a wire bar method. In the case of performing application using any of the coating methods, single layer coating is preferable.

The coating film formed on the support is subjected to an alignment treatment to align the polymerizable liquid crystal compound in the coating film.

The alignment treatment can be performed by drying the coating film at room temperature or by heating the coating film. In the case of a thermotropic liquid crystal compound, generally, the liquid crystal phase formed by the alignment treatment can be transferred by changing temperature or pressure. In the case of a liquid crystal compound having lyotropic properties, the liquid crystal phase can be transferred by the compositional ratio such as the amount of a solvent.

The conditions of the case of heating the coating film are not particularly limited. However, the heating temperature is preferably 50° C. to 150° C. and the heating time is preferably 10 seconds to 5 minutes.

Next, a curing treatment is performed on the coating film in which the polymerizable liquid crystal compound is aligned.

The method of the curing treatment performed on the coating film in which the polymerizable liquid crystal compound is aligned is not particularly limited, and examples thereof include a photoirradiation treatment and a heating treatment. Among these, from the viewpoint of production suitability, a photoirradiation treatment is preferable and an ultraviolet irradiation treatment is more preferable.

The irradiation conditions for the photoirradiation treatment are not particularly limited and the irradiation amount is preferably 50 to 1000 mJ/cm².

(Positive C-Plate)

The positive C-plate satisfies the following requirement 2 with the positive A-plate.

{ReA(450)/ReA(550)−0.10}≤RthC(450)/RthC(550)/≤{ReA(450)/ReA(550)+0.10}, Requirement 2:

ReA(450) and ReA(550) represent in-plane retardations of the positive A-plate at wavelengths 450 nm and 550 nm, respectively, and

RthC(450) and RthC(550) represent retardations of the positive C-plate in a thickness direction at wavelengths 450 nm and 550 nm, respectively.

In the requirement 2 indicates that the RthC(450)/RthC(550) of the positive C-plate is in a range of ReA(450)/ReA(550)±0.10. By satisfying this requirement, the desired effect (particularly, suppression of a change in tint) can be obtained.

In the relationship, from the viewpoint that the effect of the present invention is more excellent, the positive C-plate and the positive A-plate preferably satisfy the following requirement 2A.

{ReA(450)/ReA(550)−0.06}≤RthC(450)/RthC(550)/≤{ReA(450)/ReA(550)+0.06}, Requirement 2:

The requirement 2A indicates that the RthC(450)/RthC(550) of the positive C-plate is in a range of ReA(450)/ReA(550)±0.06.

The RthC(450)/RthC(550) of the positive C-plate is not particularly limited and is 0.65 or more and less than 1.00 in many cases. In the relationship, from the viewpoint that the effect of the present invention is more excellent, the positive C-plate preferably satisfies the following requirement 3.

0.67≤RthC(450)/RthC(550)≤0.80 Requirement 3:

From the viewpoint that the effect of the present invention is more excellent, it is preferable that the positive C-plate exhibits reverse wavelength dispersibility. The reverse wavelength dispersibility is preferably exhibited in the visible light range.

The positive C-plate exhibiting forward wavelength dispersibility means that the retardation of the positive C-plate in the thickness direction exhibits forward wavelength dispersibility. That is, this means that as the measurement wavelength increases, the retardation of the positive C-plate in the thickness direction decreases. In other words, the RthC(450)/RthC(550), RthC(500)/RthC(550), RthC(600)/RthC(550), and RthC(650)/RthC(550) described later satisfy the following relationship Y.

{RthC(450)/RthC(550)}<{RthC(500)/RthC(550)}<{RthC(600)/RthC(550)}<{RthC(650)/RthC(550)} Relationship Y:

In order to set the retardation of the positive C-plate in the thickness direction to appropriately exhibit reverse wavelength dispersability, specifically, the RthC(450)/RthC(550) of the positive C-plate is preferably 0.63 to 0.90 and more preferably 0.67 to 0.80. The RthC(450)/RthC(550) represents a ratio of RthC(450), which is the retardation of the positive C-plate in the thickness direction at a wavelength of 450 nm, with respect to RthC(550), which is the retardation of the positive C-plate in the thickness direction at a wavelength of 550 nm.

In addition, the RthC(500)/RthC(550) of the positive C-plate is preferably 0.83 to 0.99 and more preferably 0.89 to 0.97. The RthC(500)/RthC(550) represents a ratio of RthC(500), which is the retardation of the positive C-plate in the thickness direction at a wavelength of 500 nm, with respect to RthC(550), which is the retardation of the positive C-plate in the thickness direction at a wavelength of 550 nm.

In addition, the RthC(600)/RthC(550) of the positive C-plate is preferably 1.01 to 1.10 and more preferably 1.01 to 1.06. The RthC(600)/RthC(550) represents a ratio of RthC(600), which is the retardation of the positive C-plate in the thickness direction at a wavelength of 600 nm, with respect to RthC(550), which is the retardation of the positive C-plate in the thickness direction at a wavelength of 550 nm.

In addition, the RthC(650)/RthC(550) of the positive C-plate is preferably 1.03 to 1.16 and more preferably 1.04 to 1.10. The RthC(650)/RthC(550) represents a ratio of RthC(650), which is the retardation of the positive C-plate in the thickness direction at a wavelength of 650 nm, with respect to RthC(550), which is the retardation of the positive C-plate in the thickness direction at a wavelength of 550 nm.

The RthC(550), which is the retardation of the positive C-plate in the thickness direction at a wavelength of 550 nm, is not particularly limited, but from the viewpoint that the effect of the present invention is more excellent, the RthC(550) is preferably −90 to −50 nm, more preferably −80 to −60 nm, and even more preferably −75 to −65 nm.

The ReC(550), which is the in-plane retardation of the positive C-plate at a wavelength of 550 nm, is preferably 0 to 10 nm and more preferably 0 to 5 nm from the viewpoint that the effect of the present invention is more excellent.

The thickness of the positive C-plate is not particularly limited and is adjusted to be in a predetermined range satisfying the above requirement 2. From the viewpoint of reducing the thickness of the phase difference film, the thickness is preferably 6 μm or less, more preferably 0.5 to 5.0 μm, and even more preferably 1 to 3.0 μm.

In the present specification, the thickness of the positive C-plate means the average thickness of the positive C-plate. The thickness is obtained by measuring the thickness at 5 or more random points in the positive C-plate and arithmetically averaging those values.

The material constituting the positive C-plate is not particularly limited as long as the above characteristics are exhibited, and the aspects described in the positive A-plate may be used. Among these, from the viewpoint of easily controlling the above characteristics, the positive C-plate is preferably a layer formed by fixing a liquid crystal compound (rod-like liquid crystal compound or disk-like liquid crystal compound) having a polymerizable group through polymerization or the like. In this case, after the layer is formed, the liquid crystal compound does not need to exhibit liquid crystallinity any longer. Among these, the positive C-plate is preferably formed by using a compound represented by Formula (I) as in the positive A-plate.

The method of forming the first positive C-plate is not particularly limited and known methods can be adopted. For example, the above-mentioned method of forming the positive A-plate may be used.

In a case where the positive A-plate is formed by using a composition A including a liquid crystal compound and the positive C-plate is also formed by using a composition C including a liquid crystal compound, it is preferable that the kind of the liquid crystal compound included in the composition A is the same as the kind of the liquid crystal compound included in the composition C.

(Other Layers)

The phase difference film may include layers other than the positive A-plate and the positive C-plate within a range not impairing the effect of the present invention.

For example, the phase difference film may include an alignment film having a function of defining the alignment direction of the liquid crystal compound. The position where the alignment film is arranged is not particularly limited and for example, the alignment film may be arranged between the positive A-plate and the positive C-plate.

The material constituting the alignment film and the thickness of the alignment film are as described above.

In addition, the phase difference film may include an adhesive layer or a pressure sensitive adhesive layer for bonding the respective layers.

The phase difference film may include a support. As the support, a so-called transparent support is preferable.

Further, as the transparent support, a known transparent support can be used. In addition, as the material for forming the transparent support, a cellulose-based polymer typified by triacetyl cellulose (hereinafter, referred to as cellulose acylate), a thermoplastic norbornene-based resin (ZEONEX and ZEONOR manufactured by Zeon Corporation, ARTON manufactured by JSR Corporation, or the like), an acrylic resin, or a polyester-based resin may be used.

The method of producing the phase difference film is not particularly limited and for example, a method of laminating the positive A-plate and the positive C-plate respectively prepared through an adhesive or a pressure sensitive adhesive may be used.

The phase difference film can be applied for various applications, and particularly, can be suitably applied to antireflection application. More specifically, the circularly polarizing plate can be suitably applied to a display device such as an organic EL display device for the antireflection application.

<Circularly Polarizing Plate>

A circularly polarizing plate according to an embodiment of the present invention will be described with reference to the drawings. FIG. 2 is a cross-sectional view showing a circularly polarizing plate according to an embodiment of the present invention.

A circularly polarizing plate 16 has a polarizer 18, a positive A-plate 12, and a positive C-plate 14 in this order. In FIG. 2, in the circularly polarizing plate, a polarizer, a positive A-plate, and a positive C-plate are arranged in this order. There is no limitation thereto. For example, a polarizer, a positive C-plate, and a positive A-plate may be arranged in this order.

Further, in FIG. 3, the relationship between the absorption axis of the polarizer 18 and the in-plane slow axis of the positive A-plate 12 is shown. In FIG. 3, the arrow in the polarizer 18 represents the direction of the absorption axis, and the arrow in the positive A-plate 12 represents the direction of the in-plane slow axis in the layer. In FIG. 3, the description of the positive C-plate 14 is omitted.

Hereinafter, each member included in the circularly polarizing plate 16 will be described in detail.

First, the aspects of the positive A-plate 12 and the positive C-plate 14 included in the circularly polarizing plate 16 are as described above.

(Polarizer)

The polarizer may be a member having a function of converting light into specific linearly polarized light (linear polarizer) and for example, an absorptive type polarizer may be used.

As the absorptive type polarizer, for example, an iodine-based polarizer, a dye-based polarizer using a dichroic dye, a polyene-based polarizer, and the like may be used. The iodine-based polarizer and the dye-based polarizer include a coating type polarizer and a stretching type polarizer, and any one of these polarizers can be applied. Of these polarizers, a polarizer, which is prepared by allowing polyvinyl alcohol to adsorb iodine or a dichroic dye, and performing stretching, is preferable.

In addition, examples of a method of obtaining a polarizer by performing stretching and dyeing in a state of a laminated film in which a polyvinyl alcohol layer is formed on a base material include methods disclosed in JP5048120B, JP5143918B, JP5048120B, JP4691205B, JP4751481B, and JP4751486B, and known technologies related to these polarizers can be preferably used.

Among these, from the point of handleability, the polarizer is preferably a polarizer containing a polyvinyl alcohol-based resin (a polymer including —CH₂—CHOH— as a repeating unit, in particular, at least one selected from the group consisting of polyvinyl alcohol and an ethylene-vinyl alcohol copolymer is preferable).

The thickness of the polarizer is not particularly limited but from the viewpoint of achieving excellent handleability and excellent optical properties, the thickness is preferably 35 μm or less, more preferably 3 to 25 μm, and even more preferably 4 to 15 μm. Within the thickness range, an image display device can be made thin.

As shown in FIG. 3, an angle θ formed between the absorption axis of the polarizer 18 and the in-plane slow axis of the positive A-plate 12 is preferably 45°±10° from the viewpoint that the effect of the present invention is more excellent. That is, the angle θ is preferably 35°to 55°. In this range, from the viewpoint that the effect of the present invention is more excellent, the angle θ formed between the absorption axis of the polarizer 18 and the in-plane slow axis of the positive A-plate 12 is more preferably 40° to 50° and even more preferably 420 to 480.

The angle means an angle formed between the absorption axis of the polarizer 18 and the in-plane slow axis of the positive A-plate 12 in a case of being viewed in the normal direction of the surface of the polarizer 18.

(Other Layers)

The circularly polarizing plate 16 may include layers other than the polarizer 18, the positive A-plate 12, and the positive C-plate 14 within a range not impairing the effect of the present invention.

For example, the circularly polarizing plate 16 may include an alignment film having a function of defining the alignment direction of a liquid crystal compound. The position where the alignment layer is arranged is not particularly limited, but for example, may be arranged between the positive A-plate 12 and the positive C-plate 14.

The material constituting the alignment film and the thickness of the alignment film are as described above.

In addition, the circularly polarizing plate 16 may include an adhesive layer or a pressure sensitive adhesive layer for bonding the respective layers.

Further, a polarizer protective film may be arranged on the surface of the polarizer.

The configuration of the polarizer protective film is not particularly limited, and may be, for example, a transparent support or a hardcoat layer, or a laminate of a transparent support and a hardcoat layer.

A known layer can be used as a hardcoat layer and the hardcoat layer may be, for example, a layer obtained by polymerizing and curing the above-mentioned polyfunctional monomer.

Further, as a transparent support, a known transparent support can be used. For example, as the material for forming the transparent support, a cellulose-based polymer typified by triacetyl cellulose (hereinafter, referred to as cellulose acylate), a thermoplastic norbornene-based resin (ZEONEX and ZEONOR manufactured by Zeon Corporation, ARTON manufactured by JSR Corporation, or the like), a (meth)acrylic resin, or a polyester-based resin may be used.

The thickness of the polarizer protective film is not particularly limited and from the viewpoint of being capable of reducing the thickness of the polarizing plate, the thickness is preferably 40 μm or less and more preferably 25 μm or less.

The method of producing the circularly polarizing plate is not particularly limited and for example, a method of laminating the polarizer, the positive A-plate and the positive C-plate respectively prepared through an adhesive or a pressure sensitive adhesive may be used.

The circularly polarizing plate can be applied for various applications, and particularly, can be suitably applied to antireflection application. More specifically, the circularly polarizing plate can be suitably applied to a display device such as an organic EL display device for the antireflection application.

<Organic EL Display Device>

An organic EL display device according to an embodiment of the present invention will be described with reference to the drawing. FIG. 4 is a cross-sectional view showing an organic EL display device according to an embodiment of the present invention.

An organic EL display device 20 has a polarizer 18, a positive A-plate 12, a positive C-plate 14, and an organic EL display panel 22 in this order. As shown in FIG. 4, the polarizer 18 in the circularly polarizing plate 16 is arranged on the viewing side.

The organic EL display panel 22 is a display panel constituted using an organic EL element in which an organic light emitting layer (organic electroluminescent layer) is held between electrodes (between a cathode and an anode).

The configuration of the organic EL display panel 22 is not particularly limited and a known configuration is adopted.

### EXAMPLES

Hereinafter, the features of the present invention will be more specifically described with reference to Examples and Comparative Examples. The materials, the amount of the materials used, the ratio between the materials, the content and the procedures of treatment, and the like shown in the following examples can be appropriately modified as long as the modification does not depart from the gist of the present invention. Accordingly, the scope of the present invention is not limited to the following specific examples.

### Example 1

(Formation of Aligmnent Film P-1)

The following coating liquid for forming an alignment film P-1 was applied to a glass substrate by spin coating, and the glass substrate coated with the coating solution for forming an alignment film P-1 was dried for 120 seconds with hot air at 100° C. to form an alignment film

Coating Liquid for Forming Alignment Film P-1

| | |
|---|---|
| Polyvinyl alcohol (PVA 203, manufactured | 2.0 parts by mass |
| by Kuraray Co., Ltd.) | |
| Water | 98.0 parts by mass |

(Formation of Positive A-Plate A-1)

The alignment film P-1 was subjected to an alignment treatment by a rubbing method, and then the following composition A-1 was applied to the alignment film P-1 by a spin coating method. The coating film formed on the alignment film P-1 was heated to 180° C. on a hot plate and then cooled to 140° C. Thereafter, by irradiating the coating film with ultraviolet light of 500 mJ/cm² at a wavelength of 365 nm using a high pressure mercury lamp under a nitrogen atmosphere, the alignment of the liquid crystal compound was fixed to prepare a film A-1 including a positive A-plate A-1. The thickness of the positive A-plate A-1 is shown in Table 1.

Composition A-1

| | | |
|---|---|---|
| Liquid crystal compound L-1 | 90.00 | parts by mass |
| Liquid crystal compound L-2 | 5.00 | parts by mass |
| Liquid crystal compound L-3 | 5.00 | parts by mass |
| Polymerization initiator P1-1 | 0.50 | parts by mass |
| Leveling agent T-1 | 0.20 | parts by mass |
| Chloroform | 570.63 | parts by mass |

Liquid crystal compound L-1 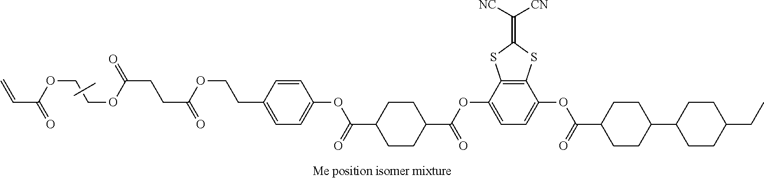
Liquid crystal compound L-2 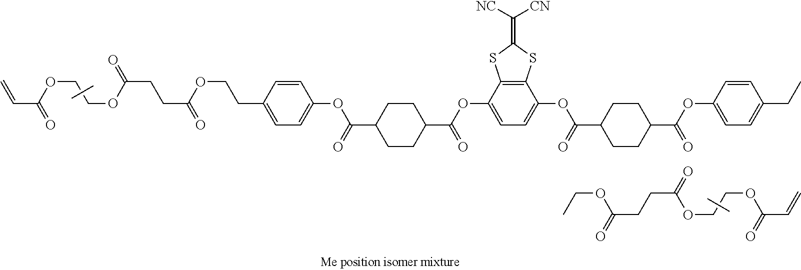
Liquid crystal compound L-3 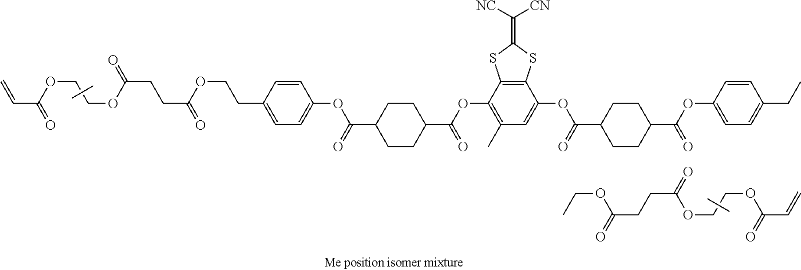
Polymerization initiator PI-1 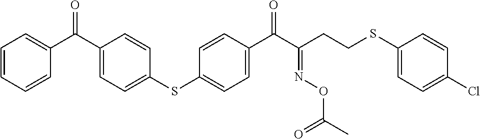 [SMILES: CC(=O)O/N=C(\CCSc1ccc(Cl)cc1)C(=O)c1ccc(Sc2ccc(C(=O)c3ccccc3)cc2)cc1]
Leveling agent T-1

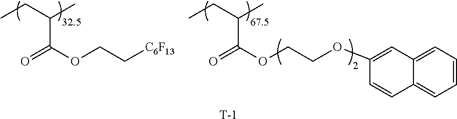

(Formation of Positive C-Plate C-1)

The following composition C-1 was applied to the alignment film P-1 by a spin coating method. The coating film formed on the alignment film P-1 was heated to 180° C. on a hot plate and then cooled to 130° C. Thereafter, by irradiating the coating film with ultraviolet light of 500 mJ/cm² at a wavelength of 365 nm using a high pressure mercury lamp under a nitrogen atmosphere, the alignment of the liquid crystal compound was fixed to prepare a film C-1 including a positive C-plate C-1. The thickness of the positive C-plate C-1 is shown in Table 1.

Composition C-1

| | | |
|---|---|---|
| Liquid crystal compound L-1 | 90.00 | parts by mass |
| Liquid crystal compound L-2 | 5.00 | parts by mass |
| Liquid crystal compound L-3 | 5.00 | parts by mass |
| Polymerization initiator PI-1 | 3.00 | parts by mass |
| Leveling agent T-2 | 0.40 | parts by mass |
| Leveling agent T-3 | 0.20 | parts by mass |
| Compound L-4 | 1.00 | part by mass |
| Compound L-5 | 2.50 | parts by mass |
| Chloroform | 570.63 | parts by mass |

Leveling agent T-2 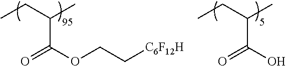
Leveling agent T-3 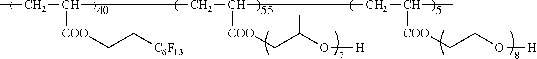
Compound L-4 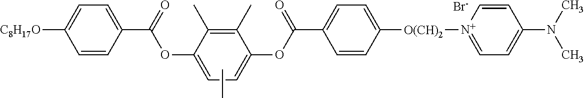
Compound L-5

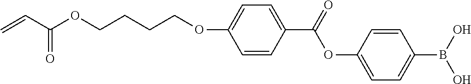 [SMILES: C=CC(=O)OCCCCOc1ccc(C(=O)Oc2ccc(B(O)O)cc2)cc1]

(Formation of Circularly Polarizing Plate 1)

The surface of TD80UL (manufactured by Fujifilm Corporation) as a support was subject to alkaline saponification. Specifically, the support was immersed in 1.5 N an aqueous sodium hydroxide solution at 55° C. for 2 minutes and taken out and the taken-out support was washed in a water bath at room temperature and was neutralized with 0.1 N sulfuric acid at 30° C. Thereafter, the obtained support was washed again in a washing bath at room temperature and further dried by hot air at a temperature of 100° C.

Subsequently, a roll-shaped polyvinyl alcohol film having a thickness of 80 μm was continuously stretched 5 times in an aqueous iodine solution, and the stretched film was dried to obtain a polarizer having a thickness of 20 μm.

The obtained polarizer and the alkali saponified support (TD80UL) were laminated to obtain a polarizing plate with the polarizer exposed on one side.

Next, the polarizer in the polarizing plate and the positive A-plate A-1 in the film A-1 were laminated through a pressure sensitive adhesive such that the angle formed between the absorption axis of the polarizer and the slow axis of the positive A-plate A-1 was 45°. Subsequently, the glass substrate was peeled off, and only the positive A-plate A-1 was transferred onto the polarizer.

Subsequently, according to the same procedure, the positive C plate C-1 was transferred onto the positive A-plate A-1 and thus a circularly polarizing plate 1 was prepared.

### Example 2

(Saponification of Support)

As a support, a commercially available triacetyl cellulose film “Z-TAC” (manufactured by Fujifilm Corporation) was used. The support was allowed to pass through a dielectric heating roll at a temperature of 60° C., and the surface temperature of the support was raised to 40° C. Thereafter, an alkaline solution shown below was applied to one surface of the support using a bar coater at a coating amount of 14 ml/m², heated to 110° C., and further transported below a steam type far infrared heater manufactured by Noritake Co., Limited for 10 seconds. Subsequently, 3 ml/m² of pure water was applied onto the surface of the support using the same bar coater. Next, after washing with a fountain coater and drainage with an air knife were repeated three times, the support was transported to a drying zone at 70° C. for 10 seconds to dry the support, and thus an alkali saponified support was prepared.

Alkaline solution

| | |
|---|---|
| Potassium hydroxide | 4.70 parts by mass |
| Water | 15.80 parts by mass |
| Isopropanol | 63.70 parts by mass |
| Surfactant | 1.0 part by mass |
| SF-1:C₁₄H₂₉O(CH₂CH₂O)₂OH | |
| Propylene glycol | 14.8 parts by mass |

(Formation of Alignment Film P-2)

The following coating liquid for forming an alignment film P-2 was continuously applied to the alkali saponified support with a #8 wire bar. The support having a coating film formed thereon was dried with hot air at a temperature of 60° C. for 60 seconds and then further dried with hot air at a temperature of 100° C. for 120 seconds to form an alignment film P-2.

Coating Liquid for Forming Alignment Film P-2

| | | |
|---|---|---|
| Modified polyvinyl alcohol below | 2.40 | parts by mass |
| isopropyl alcohol | 1.60 | parts by mass |
| Methanol | 36.00 | parts by mass |
| Water | 60.00 | parts by mass |

Modified polyvinyl alcohol

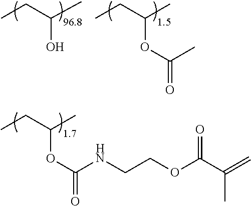

(Formation of Positive A-Plate A-2)

The alignment film P-2 was subjected to an alignment treatment by a rubbing method, and then the following composition A-2 was applied to the alignment film P-2 using a wire bar. The coating film formed on the alignment film P-2 was heated to 140° C. on a hot plate and then cooled to 60° C. Thereafter, by irradiating the coating film with ultraviolet light of 500 mJ/cm² at a wavelength of 365 nm using a high pressure mercury lamp under a nitrogen atmosphere, the alignment of the liquid crystal compound was fixed to prepare a film A-2 including a positive A-plate A-2. The thickness of the positive A-plate A-2 is shown in Table 1.

Composition A-2

| | | |
|---|---|---|
| Liquid crystal compound L-6 | 100.00 | parts by mass |
| Polymerization initiator PI-1 | 0.50 | parts by mass |
| Leveling agent T-1 | 0.20 | parts by mass |
| Methyl ethyl ketone | 302.10 | parts by mass |

Liquid crystal compound L-6

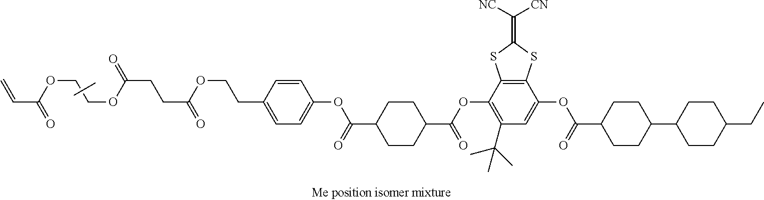

(Formation of Alignment Film P-2)

The following coating liquid for forming an alignment film P-2 was continuously applied to the support (TD80UL (manufactured by Fujifilm Corporation)) with a #8 wire bar. The TD80UL having a coating film formed thereon was dried with hot air at a temperature of 60° C. for 60 seconds and then further dried with hot air at a temperature of 100° C. for 120 seconds to form an alignment film P-2.

(Formation of Positive C-Plate C-2)

The following composition C-2 was applied to the alignment film P-2 using a wire bar. The coating film formed on the alignment film P-2 heated to 140° C. on a hot plate and then cooled to 100° C. Thereafter, by irradiating the coating film with ultraviolet light of 500 mJ/cm^{z} at a wavelength of 365 nm using a high pressure mercury lamp under a nitrogen atmosphere, the alignment of the liquid crystal compound was fixed to prepare a film C-2 including a positive C-plate C-2. The thickness of the positive C-plate C-2 is shown in Table 1.

Composition C-2

| | |
|---|---|
| Liquid crystal compound L-6 | 100.00 parts by mass |
| Polymerization initiator PI-1 | 3.00 parts by mass |
| Leveling agent T-2 | 0.40 parts by mass |
| Leveling agent T-3 | 0.20 parts by mass |
| Compound L-4 | 1.00 part by mass |
| Compound L-5 | 2.50 parts by mass |
| Chloroform | 906.30 parts by mass |

(Formation of Circularly Polarizing Plate 2)

The surface of TD80UL (manufactured by Fujifilm Corporation) as a support was subject to alkaline saponification. Specifically, the support was immersed in 1.5 N an aqueous sodium hydroxide solution at 55° C. for 2 minutes and taken out and the taken-out support was washed in a water bath at room temperature and was neutralized with 0.1 N sulfuric acid at 30° C. Thereafter, the obtained support was washed again in a washing bath at room temperature and further dried by hot air at a temperature of 100° C.

Subsequently, a roll-shaped polyvinyl alcohol film having a thickness of 80 μm was continuously stretched 5 times in an aqueous iodine solution, and the stretched film was dried to obtain a polarizer having a thickness of 20 μm.

The obtained polarizer and the alkali saponified support (TD80UL) were laminated to obtain a polarizing plate with the polarizer exposed on one side.

Next, the positive A-plate A-2 in the film A-2 and the positive C-plate C-2 in the film C-2 were laminated through a pressure sensitive adhesive and then the support in the film C-2 was peeled off to prepare a phase difference film. Subsequently, the polarizer in the polarizing plate and the support in the film A-2 included in the phase difference film were laminated through a pressure sensitive adhesive such that the angle formed between the absorption axis of the polarizer and the slow axis of the positive A-plate A-2 was 45°. Thus, a circularly polarizing plate 2 was prepared.

### Example 3

A circularly polarizing plate 3 was prepared in the same manner as in Example 2 except that the composition A-2 was changed to the following composition A-3, the composition C-2 was changed to a composition C-3, and the thickness of the positive A-plate and the positive C-plate was adjusted.

Composition A-3

| | | |
|---|---|---|
| Liquid crystal compound L-7 | 42.50 | parts by mass |
| Liquid crystal compound L-8 | 42.50 | parts by mass |
| Liquid crystal compound L-2 | 7.50 | parts by mass |
| Liquid crystal compound L-3 | 7.50 | parts by mass |
| Polymerization initiator PI-1 | 0.50 | parts by mass |
| Leveling agent T-1 | 0.20 | parts by mass |
| Methyl ethyl ketone | 214.00 | parts by mass |

Liquid crystal compound L-7 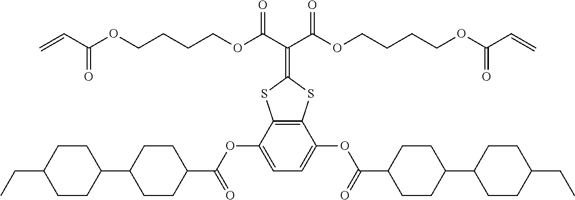 [SMILES: C=CC(=O)OCCCCOC(=O)C(C(=O)OCCCCOC(=O)C=C)=C1Sc2c(OC(=O)C3CCC(C4CCC(CC)CC4)CC3)ccc(OC(=O)C3CCC(C4CCC(CC)CC4)CC3)c2S1]
Liquid crystal compound L-8

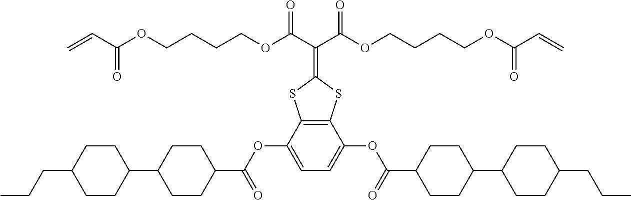 [SMILES: C=CC(=O)OCCCCOC(=O)C(C(=O)OCCCCOC(=O)C=C)=C1Sc2c(OC(=O)C3CCC(C4CCC(CCC)CC4)CC3)ccc(OC(=O)C3CCC(C4CCC(CCC)CC4)CC3)c2S1]

Composition C-3

| | | |
|---|---|---|
| Liquid crystal compound L-7 | 42.50 | parts by mass |
| Liquid crystal compound L-8 | 42.50 | parts by mass |
| Liquid crystal compound L-2 | 7.50 | parts by mass |
| Liquid crystal compound L-3 | 7.50 | parts by mass |
| Polymerization initiator PI-1 | 3.00 | parts by mass |
| Leveling agent T-2 | 0.40 | parts by mass |
| Leveling agent T-3 | 0.20 | parts by mass |
| Compound L-4 | 1.00 | part by mass |
| Compound L-5 | 2.50 | parts by mass |
| Methyl ethyl ketone | 570.60 | parts by mass |

### Example 4

A circularly polarizing plate 4 was prepared in the same manner as in Example 1 except that the composition A-1 was changed to the following composition A-4, the composition C-1 was changed to the following composition C-4, and the thickness of the positive A-plate and the positive C-plate was adjusted.

Composition A-4

| | | |
|---|---|---|
| Liquid crystal compound L-1 | 25.00 | parts by mass |
| Liquid crystal compound L-3 | 75.00 | parts by mass |
| Polymerization initiator PI-1 | 0.50 | parts by mass |
| Leveling agent T-1 | 0.20 | parts by mass |
| Chloroform | 570.63 | parts by mass |

Composition C-4

| | | |
|---|---|---|
| Liquid crystal compound L-1 | 25.00 | parts by mass |
| Liquid crystal compound L-3 | 75.00 | parts by mass |
| Polymerization initiator PI-1 | 3.00 | parts by mass |
| Leveling agent T-2 | 0.40 | parts by mass |
| Leveling agent T-3 | 0.20 | parts by mass |
| Compound L-4 | 1.00 | part by mass |
| Compound L-5 | 2.50 | parts by mass |
| Chloroform | 570.63 | parts by mass |

### Example 5

A circularly polarizing plate 5 was prepared in the same manner as in Example 2 except that the composition A-2 was changed to the following composition A-5, the composition C-2 was changed to the following composition C-5, and the thickness of the positive A-plate and the positive C-plate was adjusted.

Composition A-5

| | | |
|---|---|---|
| Liquid crystal compound L-1 | 95.00 | parts by mass |
| Liquid crystal compound L-3 | 5.00 | parts by mass |
| Polymerization initiator PI-1 | 0.50 | parts by mass |
| Leveling agent T-1 | 0.20 | parts by mass |
| Methyl ethyl ketone | 214.00 | parts by mass |

Composition C-5

| | | |
|---|---|---|
| Liquid crystal compound L-1 | 95.00 | parts by mass |
| Liquid crystal compound L-3 | 5.00 | parts by mass |
| Polymerization initiator PI-1 | 3.00 | parts by mass |
| Leveling agent T-2 | 0.40 | parts by mass |
| Leveling agent T-3 | 0.20 | parts by mass |
| Compound L-4 | 1.00 | part by mass |
| Compound L-5 | 2.50 | parts by mass |
| Methyl ethyl ketone | 570.60 | parts by mass |

### Example 6

A circularly polarizing plate 6 was prepared in the same manner as in Example 1 except that the composition A-1 was changed to the following composition A-6, the composition C-1 was changed to the following composition C-6, and the thickness of the positive A-plate and the positive C-plate was adjusted.

Composition A-6

| | | |
|---|---|---|
| Liquid crystal compound L-1 | 75.00 | parts by mass |
| Liquid crystal compound L-9 | 25.00 | parts by mass |
| Polymerization initiator P1-1 | 0.50 | parts by mass |
| Leveling agent T-1 | 0.20 | parts by mass |
| Chloroform | 570.63 | parts by mass |

Liquid crystal compound L-9

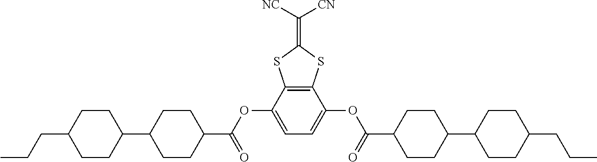 [SMILES: CCCC1CCC(C2CCC(C(=O)Oc3ccc(OC(=O)C4CCC(C5CCC(CCC)CC5)CC4)c4c3SC(=C(C#N)C#N)S4)CC2)CC1]

Composition C-6

| | | |
|---|---|---|
| Liquid crystal compound L-1 | 80.00 | parts by mass |
| Liquid crystal compound L-9 | 20.00 | parts by mass |
| Polymerization initiator PI-1 | 3.00 | parts by mass |
| Leveling agent T-2 | 0.40 | parts by mass |
| Leveling agent T-3 | 0.20 | parts by mass |
| Compound L-4 | 1.00 | part by mass |
| Compound L-5 | 2.50 | parts by mass |
| Chloroform | 570.63 | parts by mass |

### Example 7

A circularly polarizing plate 7 was prepared in the same manner as in Example 1 except that the composition C-1 was changed to the following composition C-7 and the thickness of the positive C-plate was adjusted.

Composition C-7

| | | |
|---|---|---|
| Liquid crystal compound L-1 | 70.00 | parts by mass |
| Liquid crystal compound L-9 | 30.00 | parts by mass |
| Polymerization initiator PI-1 | 3.00 | parts by mass |
| Leveling agent T-2 | 0.40 | parts by mass |
| Leveling agent T-3 | 0.20 | parts by mass |
| Compound L-4 | 1.00 | part by mass |
| Compound L-5 | 2.50 | parts by mass |
| Chloroform | 570.63 | parts by mass |

### Example 8

A circularly polarizing plate 8 was prepared in the same manner as in Example 1 except that the composition C-1 was changed to the following composition C-8 and the thickness of the positive C-plate was adjusted.

Composition C-8

| | | |
|---|---|---|
| Liquid crystal compound L-7 | 100.00 | parts by mass |
| Polymerization initiator PI-1 | 3.00 | parts by mass |
| Leveling agent T-2 | 0.40 | parts by mass |
| Leveling agent T-3 | 0.20 | parts by mass |
| Compound L-4 | 1.00 | part by mass |
| Compound L-5 | 2.50 | parts by mass |
| Chloroform | 570.63 | parts by mass |

### Example 9

A circularly polarizing plate 9 was prepared in the same manner as in Example 1 except that the composition C-1 was changed to the following composition C-9 and the thickness of the positive C-plate was adjusted.

Composition C-9

| | | |
|---|---|---|
| Liquid crystal compound L-1 | 80.00 | parts by mass |
| Liquid crystal compound L-2 | 10.00 | parts by mass |
| Liquid crystal compound L-3 | 10.00 | parts by mass |
| Polymerization initiator PI-1 | 3.00 | parts by mass |
| Leveling agent T-2 | 0.40 | parts by mass |
| Leveling agent T-3 | 0.20 | parts by mass |
| Compound L-4 | 1.00 | part by mass |
| Compound L-5 | 2.50 | parts by mass |
| Chloroform | 570.63 | parts by mass |

### Example 10

A circularly polarizing plate 10 was prepared in the same manner as in Example 1 except that the composition C-1 was changed to the following composition C-10 and the thickness of the positive C-plate was adjusted.

Composition C-10

| | | |
|---|---|---|
| Liquid crystal compound L-6 | 70.00 | parts by mass |
| Liquid crystal compound L-3 | 30.00 | parts by mass |
| Polymerization initiator PI-1 | 3.00 | parts by mass |
| Leveling agent T-2 | 0.40 | parts by mass |
| Leveling agent T-3 | 0.20 | parts by mass |
| Compound L-4 | 1.00 | part by mass |
| Compound L-5 | 2.50 | parts by mass |
| Chloroform | 570.63 | parts by mass |

### Example 11

A circularly polarizing plate 11 was prepared in the same manner as in Example 1 except that the composition C-1 was changed to the following composition C-11 and the thickness of the positive C-plate was adjusted.

Composition C-11

| | | |
|---|---|---|
| Liquid crystal compound L-1 | 50.00 | parts by mass |
| Liquid crystal compound L-2 | 25.00 | parts by mass |
| Liquid crystal compound L-3 | 25.00 | parts by mass |
| Polymerization initiator PI-1 | 3.00 | parts by mass |
| Leveling agent T-2 | 0.40 | parts by mass |
| Leveling agent T-3 | 0.20 | parts by mass |
| Compound L-4 | 1.00 | part by mass |
| Compound L-5 | 2.50 | parts by mass |
| Chloroform | 570.63 | parts by mass |

### Example 12

A circularly polarizing plate 12 was prepared in the same manner as in Example 1 except that the composition A-1 was used and the thickness of the positive A-plate was adjusted.

### Example 13

A circularly polarizing plate 13 was prepared in the same manner as in Example 1 except that the composition C-1 was used and the thickness of the positive C-plate was adjusted.

### Comparative Example 1

A circularly polarizing plate 14 was prepared in the same manner as in Example 1 except that instead of using the positive C-plate C-1, a positive C-plate C-14 prepared in the same manner as in the preparation of the positive C-plate described in paragraph 0124 of JP2015-200861A (however, the thickness of the positive C-plate was controlled to have a Rth(550) value of −69 nm) was used.

### Comparative Example 2

A circularly polarizing plate 15 was prepared in the same manner as in Comparative Example 1 except that the positive A-plate A-1 was changed to a positive A-plate A-15 prepared in the following manner.

(Preparation of Positive A-Plate A-15)

The positive A-plate A-15 was prepared in the same manner as in Example 1 except that the composition A-1 was changed to the following composition A-15, the temperature at the time of ultraviolet irradiation was changed from 140° C. to 157° C., and the thickness of the positive A-plate was adjusted.

Composition A-15

| | | |
|---|---|---|
| Liquid crystal compound L-10 | 100.00 | parts by mass |
| Polymerization initiator P1-1 | 0.50 | parts by mass |
| Leveling agent T-1 | 0.20 | parts by mass |
| Chloroform | 570.63 | parts by mass |

Liquid crystal compound L-10

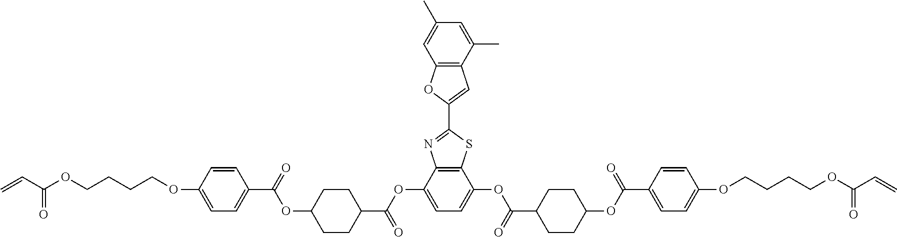 [SMILES: C=CC(=O)OCCCCOc1ccc(C(=O)OC2CCC(C(=O)Oc3ccc(OC(=O)C4CCC(OC(=O)c5ccc(OCCCCOC(=O)C=C)cc5)CC4)c4sc(-c5cc6c(C)cc(C)cc6o5)nc34)CC2)cc1]

### Comparative Example 3

A circularly polarizing plate 16 was prepared in the same manner as in Comparative Example 2 except that the composition A-15 was changed to the following composition A-16, the temperature at the time of drying was changed from 180° C. to 115° C., the temperature at the time of ultraviolet irradiation was changed from 140° C. to 80° C., and the thickness of the positive A-plate was adjusted.

Composition A-16

| | | |
|---|---|---|
| Liquid crystal compound L-2 | 42.00 | parts by mass |
| Liquid crystal compound L-3 | 42.00 | parts by mass |
| Liquid crystal compound L-11 | 16.00 | parts by mass |
| HISOLVE MTEM (manufactured by TOHO Chemical Industry Co., Ltd.) | 2.00 | parts by mass |
| NK ESTER A-200 (manufactured by Shin-Nakamura Chemical Co., Ltd.) | 1.00 | part by mass |
| Polymerization initiator P1-1 | 0.50 | parts by mass |
| Leveling agent T-1 | 0.20 | parts by mass |
| Methyl ethyl ketone | 83.00 | parts by mass |
| Cyclopentanone | 21.00 | parts by mass |

Liquid crystal compound L-11

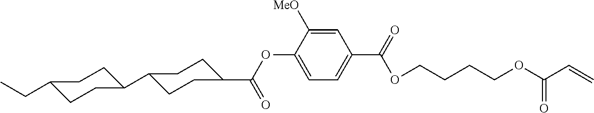 [SMILES: C=CC(=O)OCCCCOC(=O)c1ccc(OC(=O)C2CCC(C3CCC(CC)CC3)CC2)c(OC)c1]

### Comparative Example 4

A circularly polarizing plate 17 was prepared in the same manner as in Example 1 except that the composition A-1 was changed to the above composition A-16, the temperature at the time of drying was changed from 180° C. to 115° C., the temperature at the time of ultraviolet irradiation was changed from 140° C. to 80° C., the composition C-1 was changed to the following composition C-17, the temperature at the time of drying and ultraviolet irradiation was changed to 80° C., and the thickness of the positive A-plate and the positive C-plate was adjusted.

Composition C-17

| | | |
|---|---|---|
| Liquid crystal compound L-2 | 42.00 | parts by mass |
| Liquid crystal compound L-3 | 42.00 | parts by mass |
| Liquid crystal compound L-11 | 16.00 | parts by mass |
| Polymerization initiator PI-1 | 3.00 | parts by mass |
| Leveling agent T-2 | 0.40 | parts by mass |
| Leveling agent T-3 | 0.20 | parts by mass |
| Compound L-4 | 1.00 | part by mass |
| Compound L-5 | 2.50 | parts by mass |
| Chloroform | 570.63 | parts by mass |

### Comparative Example 5

An antireflection plate prepared in Example 42 of JP2015-200861A was used as Comparative Example 5.

### Example 14

(Synthesis of Polymer PA-1 Having Photo-Aligned Group)

According to the method described in Langmuir, 32(36), pp. 9245-9253 (2016), 2-hydroxyethyl methacrylate (HEMA) (reagent manufactured by Tokyo Chemical Industry Co., Ltd.) and the following cinnamic chloride derivative were used to synthesize a monomer m-1 shown below.

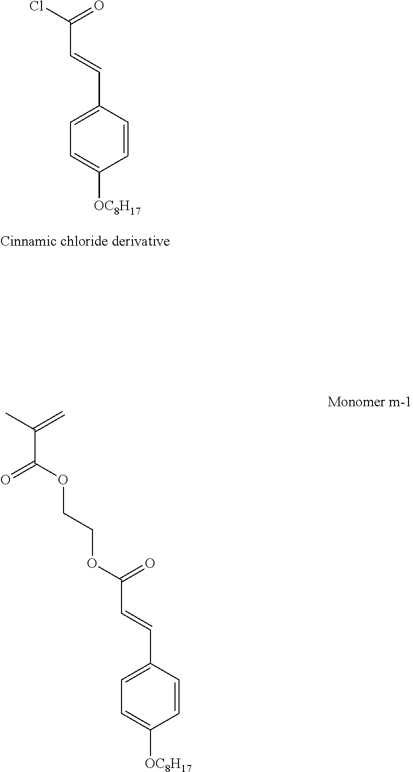

In a flask equipped with a condenser, a thermometer, and a stirrer, 2-butanone (5 parts by mass) was poured as a solvent, and refluxing was performed by a water bath heating while flowing nitrogen at 5 mL/min into the flask. Next, a solution obtained by mixing the monomer m-1 (5 parts by mass), CYCLOMER M100 (manufactured by Daicel Corporation) (5 parts by mass), 2,2′-azobis (isobutyronitrile) (1 part by mass) as a polymerization initiator, and 2-butanone (5 parts by mass) as a solvent was added dropwise into the flask for 3 hours, and further, the mixture was stirred while maintaining the reflux state for 3 hours. After completion of the reaction, the reaction solution in the flask was allowed to cool to room temperature, and 2-butanone (30 parts by mass) was added for dilution to obtain a polymer solution of about 20% by mass. The obtained polymer solution was poured into a large excess of methanol to precipitate the polymer, and the collected precipitate was separated by filtration, washed with a large amount of methanol, and then air-dried at 50° C. for 12 hours. Thus, a polymer PA-1 having a photo-aligned group represented by the following formula was obtained.

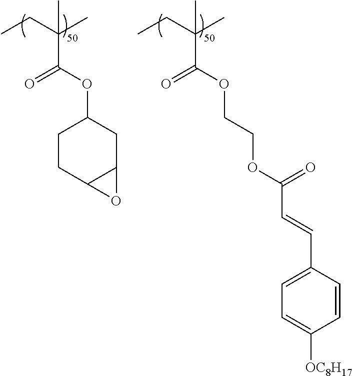

(Preparation of Alignment Film P-3)

The following coating liquid for forming an alignment film P-3 was continuously applied to a commercially available triacetyl cellulose film “Z-TAC” (manufactured by Fujifilm Corporation) using a #2.4 wire bar. The support having a coating film formed thereon was dried with hot air at a temperature of 140° C. for 120 seconds, and subsequently irradiated with polarized ultraviolet light (10 mJ/cm², using an ultra-high pressure mercury lamp). Thus, an alignment film P-3 was formed.

Coating Liquid for Forming Alignment Film P-3

| | | |
|---|---|---|
| Polymer PA-1 | 100.00 | parts by mass |
| Isopropyl alcohol | 16.50 | parts by mass |
| Butyl acetate | 1072.00 | parts by mass |
| Methyl ethyl ketone | 268.00 | parts by mass |

(Formation of Positive A-Plate A-19)

The following composition A-19 was applied to the alignment film P-3 using a bar coater. The coating film formed on the alignment film P-3 was heated to 135° C. with hot air and then cooled to 60° C. Thereafter, by irradiating the coating film with ultraviolet light of 100 mJ/cm² at a wavelength of 365 nm using a high pressure mercury lamp under a nitrogen atmosphere, and subsequently irradiating the coating film with ultraviolet light of 500 mJ/cm² while heating the coating film to 120° C., the alignment of the liquid crystal compound was fixed to prepare a film A-19 including a positive A-plate A-19. The thickness of the positive A-plate A-19 is shown in Table 1.

Composition A-19

| | | |
|---|---|---|
| Liquid crystal compound L-12 | 43.00 | parts by mass |
| Liquid crystal compound L-13 | 4300 | parts by mass |
| Liquid crystal compound L-14 | 9.00 | parts by mass |
| Liquid crystal compound L-11 | 5.00 | parts by mass |
| Polymerization initiator PI-1 | 0.50 | parts by mass |
| Leveling agent T-1 | 0.20 | parts by mass |
| Cyclopentanone | 235.00 | parts by mass |

Liquid crystal compound L-12 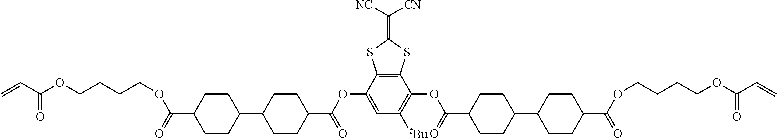 [SMILES: C=CC(=O)OCCCCOC(=O)C1CCC(C2CCC(C(=O)Oc3cc(C(C)(C)C)c(OC(=O)C4CCC(C5CCC(C(=O)OCCCCOC(=O)C=C)CC5)CC4)c4c3SC(=C(C#N)C#N)S4)CC2)CC1]
Liquid crystal compound L-13 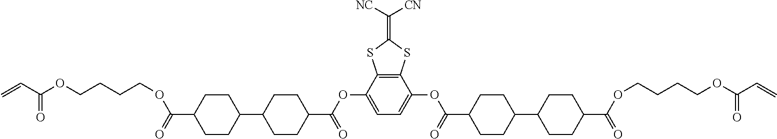 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c4c3SC(=C(C#N)C#N)S4)CC2)CC1]
Liquid crystal compound L-14

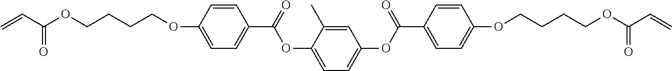 [SMILES: C=CC(=O)OCCCCOc1ccc(C(=O)Oc2ccc(OC(=O)c3ccc(OCCCCOC(=O)C=C)cc3)c(C)c2)cc1]

(Formation of Positive C-Plate C-19)

The following composition C-19 was applied to the alignment film P-1 by a spin coating method. The coating film formed on the alignment film P-1 was heated to 120° C. on a hot plate and then held at 120° C. Thereafter, by irradiating the coating film with ultraviolet light of 500 mJ/cm² at a wavelength of 365 nm using a high pressure mercury lamp under a nitrogen atmosphere, the alignment of the liquid crystal compound was fixed to prepare a film C-19 including a positive C-plate C-19. The thickness of the positive C-plate C-19 is shown in Table 1.

Composition C-19

| | | |
|---|---|---|
| Liquid crystal compound L-12 | 43.00 | parts by mass |
| Liquid crystal compound L-13 | 43.00 | parts by mass |
| Liquid crystal compound L-14 | 16.00 | parts by mass |
| Polymerization initiator PI-1 | 3.00 | parts by mass |
| Leveling agent T-2 | 0.40 | parts by mass |
| Leveling agent T-3 | 0.20 | parts by mass |
| Compound L-4 | 1.00 | parts by mass |
| Compound L-5 | 2.50 | parts by mass |
| Chloroform | 570.60 | parts by mass |

(Formation of Circularly Polarizing Plate 20)

In the same manner as in Example 1, a polarizing plate having a polarizer exposed on one side was obtained.

Next, the polarizer in the polarizing plate and the positive A-plate A-19 in the film A-19 were laminated through a pressure sensitive adhesive such that the angle formed between the absorption axis of the polarizer and the slow axis of the positive A-plate A-19 was 45°. Subsequently, by peeling off the support of the film A-19, and only the positive A-plate A-19 was transferred onto the polarizing plate. Subsequently, by laminating the positive C-plate C-19 in the film C-19 on the surface of the transferred positive A-plate A-19 using a pressure sensitive adhesive layer and peeling off the support of the film C-19, only the positive C-plate C-19 was transferred onto the positive A-plate A-19 to prepare a circularly polarizing plate 19.

### Comparative Example 6

A positive A-plate A-20 was prepared in the same manner as in Example 14 except that the composition A-19 was changed to the following composition A-20, the thickness was adjusted, and a circularly polarizing plate 20 was prepared in the same manner as in Example 1 except that the instead of using the positive C-plate C-19, a positive C-plate C-14 prepared in the same manner as in the preparation of the positive C-plate described in paragraph 0124 of JP2015-200861A (however, the thickness of the positive C-plate was controlled so as to have a Rth(550) value of −69 nm) was used.

Composition A-20

| | | |
|---|---|---|
| Liquid crystal compound L-12 | 38.50 | parts by mass |
| Liquid crystal compound L-13 | 38.50 | parts by mass |
| Liquid crystal compound L-14 | 16.00 | parts by mass |
| Liquid crystal compound L-11 | 20.00 | parts by mass |
| Polymerization initiator PI-1 | 0.50 | parts by mass |
| Leveling agent T-1 | 0.20 | parts by mass |
| Cyclopentanone | 235.00 | parts by mass |

Various evaluation results of the positive A-plates, the positive C-plates, and the circularly polarizing plates prepared in Examples 1 to 14 and Comparative Examples 1 to 6 are summarized in Table 1.

<Measurement of Optical Properties>

Using an automatic birefringence meter (KOBRA-21 ADH, manufactured by Oji Scientific Instruments), the light incident angle dependence of Re at wavelengths of 450 nm, 500 nm, 550 nm, 600 nm, and 650 nm and the tilt angle of the optical axis (that is, the inclination of the layer towards the layer surface in a direction in which the refractive index of the layer is maximized) were measured, the RcA(450), ReA(500), ReA(550), RthA(550), ReA(600), and ReA(650) of the positive A-plate were respectively obtained, and the RthC(450), RthC(500), RthC(550), ReC(550), RthC(600), and RthC(650) of the positive C-plate were respectively obtained.

<Film Thickness Measurement>

The thickness of the positive A-plate and the positive C-plate was measured using a reflection spectroscopy film thickness meter FE3000 (manufactured by Otsuka Electronics Co., Ltd.).

<Mounting of Circularly Polarizing Plate on Organic EL Display Panel and Evaluation of Display Performance>

(Mounting on Organic EL Display Device)

GALAXY S IV manufactured by SAMSUNG Co., Ltd. equipped with an organic EL display panel was decomposed, the circularly polarizing plate was peeled off, and each of the circularly polarizing plates of Examples 1 to 14 and Comparative Examples 1 to 6 was laminated on the organic EL display panel to prepare an organic EL display device.

(Evaluation of Display Performance)

The reflectivity and a change in reflection tint of the prepared organic EL display device were evaluated under light conditions.

(Reflectivity)

Using a colormeter (CM-2022, manufactured by Konica Minolta, Inc.), the measurement was performed in a specular component excluded (SCE) mode, and an obtain Y value was evaluated according to the following standards using Comparative Example 5 as a reference.

A: A case where the ratio of the Y value with respect to the Y value in Comparative Example 5 is 70% or less

B: A case where the ratio of the Y value with respect to the Y value in Comparative Example 5 is more than 70%

C: A case where the ratio of the Y value with respect to the Y value in Comparative Example 5 is more than 90%

(Change in Reflection Tint)

In a black display in which external light reflected light is most easily visible, the reflected light when fluorescent light was projected from a polar angle of 45 degrees was observed. Specifically, the reflected light in the viewing angle direction (polar angle 45 degrees, azimuthal angle 0 degrees to 165 degrees in 15 degree increments) was measured with a spectroradiometer SR-3 (manufactured by Topcon Corporation) and evaluation was performed based on the following standards using Comparative Example 5 as a reference.

For a change in reflection tint, the magnitude Δa*b* of change in tint a* and b* of reflected light at all measurement angles was defined by the following expression.

Δa*b*={square root over (Maximum a*−minimum a*)²+(maximum b*−Minimum b*)²)}

A: A case where the ratio of a change in reflection tint of reflected light with respect to a change in reflection tint of reflected light in Comparative Example 5 is 55% or less

B: A case where the ratio of a change in reflection tint of reflected light with respect to a change in reflection tint of reflected light in Comparative Example 5 is more than 55% and 75% or less

C: A case where the ratio of a change in reflection tint of reflected light with respect to a change in reflection tint of reflected light in Comparative Example 5 is more than 75% and 95% or less

D: A case where the ratio of a change in reflection tint of reflected light with respect to a change in reflection tint of reflected light in Comparative Example 5 is more than 95%

In Table 1, “Re550” represents the in-plane retardation ReA(550) of the positive A-plate at a wavelength of 550 nm.

“Re450/Re550” represents a ratio of the in-plane retardation ReA(450) of the positive A-plate at a wavelength of 450 nm with respect to the in-plane retardation ReA(550) of the positive A-plate at a wavelength of 550 nm.

Similar to the “Re450/Re550”, “Re500/Re550”, “Re600/Re550” and “Re650/Re550” respectively represent ratios of the in-plane retardation ReA of the positive A-plate at each measurement wavelength (wavelengths 500 nm, 600 nm, and 650 nm) with respect to the in-plane retardation ReA(550) of the positive A-plate at a wavelength of 550 nm.

“Rth550” represents the retardation RthC(550) of the positive C-plate in the thickness direction at a wavelength of 550 nm.

In addition, “Rth450/Rth550” represents a ratio of the retardation RthC(450) of the positive C-plate in the thickness direction at a wavelength of 450 nm with respect to the retardation RthC(550) of the positive C-plate in the thickness direction at a wavelength of 550 nm.

Similar to the “Rth450/Rth550”, “Rth500/Rth550”, “Rth600/Rth550”, and “Rth650/Rth550” respectively represent ratios of the retardation RthC of the positive C-plate in the thickness direction at each measurement wavelength (wavelengths 500 nm, 600 nm, and 650 nm) with respect to the in-plane retardation RthC(550) of the positive C-plate at a wavelength of 550 nm.

In the column “Requirement 1” a case where requirement 1 is satisfied is indicated as “A” and a case where the requirement 1 is not satisfied is indicated as “B”.

In the column “Requirement 2”, the column “Difference” indicates the value of {Rth450/Rth550}−{Re500/Re550}. In the column “Determination”, a case where requirement 2 is satisfied is indicated as “A” and a case where the requirement 2 is not satisfied is indicated as “B”.

TABLE 1

| | Positive A-plate | | | | | | | | Positive C-plate | | | | |
|---|---|---|---|---|---|---|---|---|---|---|---|---|---|
| | | | | Re450/ | Re500/ | Re600/ | Re650/ | Thickness | | | | Rth450/ | Rth500/ |
| | Kind | Re550 | Rth550 | Re550 | Re550 | Re550 | Re550 | (μm) | Kind | Rth550 | Re550 | Rth550 | Rth550 |
| Example 1 | A-1 | 138 nm | 69 nm | 0.74 | 0.92 | 1.04 | 1.06 | 2.60 | C-1 | 69 nm | 0 nm | 0.74 | 0.92 |
| Example 2 | A-2 | 138 nm | 69 nm | 0.75 | 0.93 | 1.04 | 1.06 | 3.29 | C-2 | 69 nm | 0 nm | 0.75 | 0.93 |
| Example 3 | A-3 | 138 nm | 69 nm | 0.74 | 0.92 | 1.04 | 1.06 | 5.11 | C-3 | 69 nm | 0 nm | 0.74 | 0.92 |
| Example 4 | A-4 | 138 nm | 69 nm | 0.78 | 0.94 | 1.03 | 1.04 | 2.43 | C-4 | 69 nm | 0 nm | 0.78 | 0.94 |
| Example 5 | A-5 | 138 nm | 69 nm | 0.71 | 0.91 | 1.04 | 1.07 | 2.60 | C-5 | 69 nm | 0 nm | 0.71 | 0.91 |
| Example 6 | A-6 | 138 nm | 69 nm | 0.66 | 0.90 | 1.06 | 1.09 | 2.51 | C-6 | 69 nm | 0 nm | 0.66 | 0.90 |
| Example 7 | A-1 | 138 nm | 69 nm | 0.74 | 0.92 | 1.04 | 1.06 | 2.60 | C-7 | 69 nm | 0 nm | 0.64 | 0.89 |
| Example 8 | A-1 | 138 nm | 69 nm | 0.74 | 0.92 | 1.04 | 1.06 | 2.60 | C-8 | 69 nm | 0 nm | 0.69 | 0.90 |
| Example 9 | A-1 | 138 nm | 69 nm | 0.74 | 0.92 | 1.04 | 1.06 | 2.60 | C-9 | 69 nm | 0 nm | 0.78 | 0.94 |
| Example 10 | A-1 | 138 nm | 69 nm | 0.74 | 0.92 | 1.04 | 1.06 | 2.60 | C-10 | 69 nm | 0 nm | 0.80 | 0.94 |
| Example 11 | A-1 | 138 nm | 69 nm | 0.74 | 0.92 | 1.04 | 1.06 | 2.60 | C-11 | 69 nm | 0 nm | 0.82 | 0.95 |
| Example 12 | A-1 | 142 nm | 71 nm | 0.74 | 0.92 | 1.04 | 1.06 | 2.68 | C-1 | 69 nm | 0 nm | 0.74 | 0.92 |
| Example 13 | A-1 | 138 nm | 69 nm | 0.74 | 0.92 | 1.04 | 1.06 | 2.60 | C-1 | 60 nm | 0 nm | 0.74 | 0.92 |
| Example 14 | A- | 138 nm | 69 nm | 0.75 | 0.93 | 1.04 | 1.06 | 3.00 | C-19 | 69 nm | 0 nm | 0.75 | 0.93 |
| | 19 | | | | | | | | | | | | |
| Comparative | A-1 | 138 nm | 69 nm | 0.74 | 0.92 | 1.04 | 1.06 | 2.60 | C-14 | 69 nm | 0 nm | 1.07 | 1.03 |
| Example 1 | | | | | | | | | | | | | |
| Comparative | A- | 138 nm | 69 nm | 0.82 | 0.95 | 1.02 | 1.04 | 2.76 | C-14 | 69 nm | 0 nm | 1.07 | 1.03 |
| Example 2 | 15 | | | | | | | | | | | | |
| Comparative | A- | 138 nm | 69 nm | 0.86 | 0.96 | 1.01 | 1.02 | 2.46 | C-14 | 69 nm | 0 nm | 1.07 | 1.03 |
| Example 3 | 16 | | | | | | | | | | | | |
| Comparative | A- | 138 nm | 69 nm | 0.86 | 0.96 | 1.01 | 1.02 | 2.46 | C-17 | 69 nm | 0 nm | 0.86 | 0.96 |
| Example 4 | 16 | | | | | | | | | | | | |
| Comparative | A- | 138 nm | 69 nm | 0.80 | 0.94 | 1.03 | 1.05 | 2.10 | C-18 | 97 nm | 0 nm | 0.87 | 0.96 |
| Example 5 | 18 | | | | | | | | | | | | |
| Comparative | A- | 138 nm | 69 nm | 0.86 | 0.96 | 1.01 | 1.02 | 2.42 | C-14 | 69 nm | 0 nm | 1.07 | 1.03 |
| Example 6 | 20 | | | | | | | | | | | | |

| | Positive C-plate | | | | | | Evaluation | |
|---|---|---|---|---|---|---|---|---|
| | Rth600/ | Rth650/ | Thickness | | Requirement 2 | | | Change in |
| | Rth550 | Rth550 | (μm) | Requirement 1 | Difference | Determination | Reflectivity | reflection tint |
| Example 1 | 1.04 | 1.06 | 1.30 | A | 0.00 | A | A | A |
| Example 2 | 1.04 | 1.06 | 1.64 | A | 0.00 | A | A | A |
| Example 3 | 1.04 | 1.06 | 2.56 | A | 0.00 | A | A | A |
| Example 4 | 1.03 | 1.04 | 1.21 | A | 0.00 | A | B | A |
| Example 5 | 1.04 | 1.07 | 1.30 | A | 0.00 | A | A | A |
| Example 6 | 1.06 | 1.09 | 1.25 | A | 0.00 | A | B | B |
| Example 7 | 1.06 | 1.10 | 1.21 | A | −0.10 | A | A | B |
| Example 8 | 1.05 | 1.08 | 2.56 | A | −0.05 | A | A | A |
| Example 9 | 1.03 | 1.04 | 1.35 | A | 0.04 | A | A | A |
| Example 10 | 1.03 | 1.04 | 1.47 | A | 0.06 | A | A | A |
| Example 11 | 1.02 | 1.04 | 1.25 | A | 0.08 | A | A | B |
| Example 12 | 1.04 | 1.06 | 1.30 | A | 0.00 | A | B | A |
| Example 13 | 1.04 | 1.06 | 1.13 | A | 0.00 | A | A | A |
| Example 14 | 1.04 | 1.06 | 1.21 | A | 0.00 | A | A | A |
| Comparative | 0.97 | 0.95 | 0.58 | A | 0.33 | B | A | D |
| Example 1 | | | | | | | | |
| Comparative | 0.97 | 0.95 | 0.58 | B | 0.25 | B | C | A |
| Example 2 | | | | | | | | |
| Comparative | 0.97 | 0.95 | 0.58 | B | 0.21 | B | C | A |
| Example 3 | | | | | | | | |
| Comparative | 1.01 | 1.02 | 1.23 | B | 0.00 | A | C | A |
| Example 4 | | | | | | | | |
| Comparative | 1.01 | 1.01 | 0.81 | B | 0.07 | A | C | D |
| Example 5 | | | | | | | | |
| Comparative | 0.97 | 0.95 | 0.58 | B | 0.21 | B | C | A |
| Example 6 | | | | | | | | |

As shown in Table 1, in the case of the organic EL display device (and the phase difference film) according to the embodiment of the present invention, the desired effect was confirmed.

Among these, from the comparison of Examples 1 to 6, it was confirmed that the effect was more excellent from the viewpoint of reflectivity in a case where the requirement 1A (0.68≤ReA(450)/ReA(550)≤0.76) was satisfied.

In addition, from the comparison of Examples 7 to 11, it was confirmed that the effect was more excellent from the viewpoint of a change in reflection tint in a case where the requirement 2A was satisfied.

In addition, from the comparison of Examples 1 and 12, it was confirmed that the effect was more excellent from the viewpoint of reflectivity in a case where the in-plane retardation ReA(550) of the positive A-plate at a wavelength of 550 nm was 140 nm or less.

### EXPLANATION OF REFERENCES

10: phase difference film
12: positive A-plate
14: positive C-plate
16: circularly polarizing plate
18: polarizer
20: organic EL display device
22: organic EL display panel

What is claimed is:

1. An organic electroluminescent display device comprising:
an organic electroluminescent display panel; and
a circularly polarizing plate arranged on the organic electroluminescent display panel,
wherein the circularly polarizing plate includes a polarizer and a phase difference film,
the phase difference film includes a positive A-plate and a positive C-plate,
the positive A-plate exhibits reverse wavelength dispersibility,
the positive A-plate satisfies a following requirement 1,
the positive A-plate and the positive C-plate satisfy a following requirement 2,
0.65≤ReA(450)/ReA(550)≤0.78, and Requirement 1:
{ReA(450)/ReA(550)−0.10}≤RthC(450)/RthC(550)/≤{ReA(450)/ReA(550)+0.10}, Requirement 2:
ReA(450) and ReA(550) represent in-plane retardations of the positive A-plate at wavelengths 450 nm and 550 nm, respectively, and
RthC(450) and RthC(550) represent retardations of the positive C-plate in a thickness direction at wavelengths 450 nm and 550 nm, respectively.

2. The organic electroluminescent display device according to claim 1,
wherein the positive A-plate is formed by using a liquid crystal compound having a polymerizable group,
the liquid crystal compound is a compound represented by Formula (I),
L¹-SP¹-A¹-D³-G¹-D¹-Ar-D²-G²-D⁴-A²-SP²-L², Formula (I)
in Formula (I), D¹, D², D³ and D⁴ each independently represent a single bond, —O—CO—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—O—CO—CR³R—, —CR¹R²—CO—O—CR³R⁴—, —NR¹—CR²R³—, or —CO—NR¹—,
R¹, R², R³ and R⁴ each independently represent a hydrogen atom, a fluorine atom, or an alkyl group having 1 to 4 carbon atoms,
G¹ and G² each independently represent a divalent alicyclic hydrocarbon group having 5 to 8 carbon atoms, and one or more —CH₂— groups constituting the alicyclic hydrocarbon group may be substituted by —O—, —S— or —NH—,
A¹ and A² each independently represent a single bond, an aromatic ring having 6 or more carbon atoms or a cycloalkylene ring having 6 or more carbon atoms,
SP¹ and SP² each independently represent a single bond, a linear or branched alkylene group having 1 to 14 carbon atoms, or a divalent linking group in which one or more —CH₂— groups constituting the linear or branched alkylene group having 1 to 14 carbon atoms are substituted by —O—, —S—, —NH—, —N(Q)-, or —CO—, and Q represents a polymerizable group,
L¹ and L² each independently represent a monovalent organic group,
Ar represents any aromatic ring selected from the group consisting of groups represented by Formulae (Ar-1) to (Ar-5), 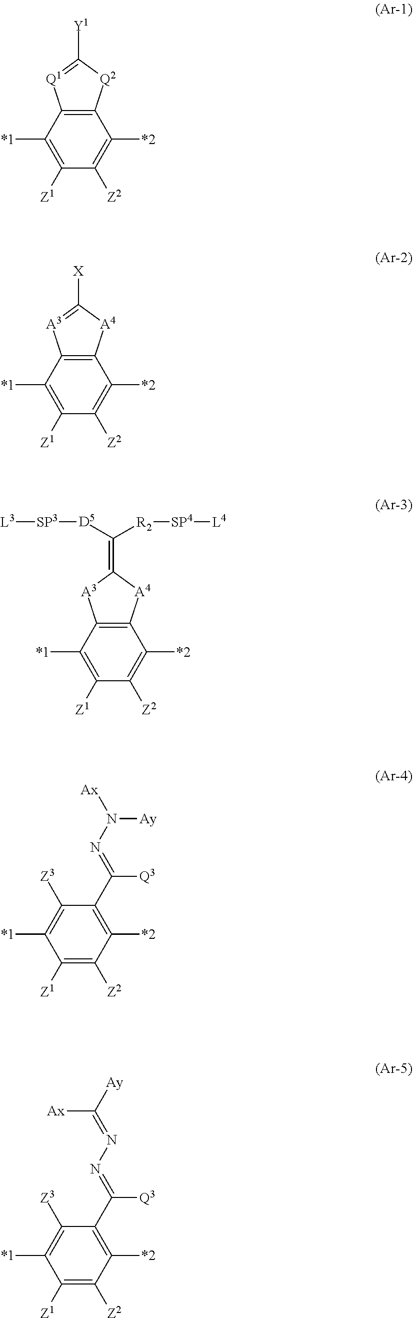
in Formulae (Ar-1) to (Ar-5), *1 represents a bonding position to D¹ and *2 represents a bonding position to D²,
Q¹ represents N or CH,
Q² represents —S—, —O—, or —N(R⁵)— and R⁵ represents a hydrogen atom or an alkyl group having 1 to 6 carbon atoms,
Y¹ represents an aromatic hydrocarbon group having 6 to 12 carbon atoms or an aromatic heterocyclic group having 3 to 12 carbon atoms, which may have a substituent,
Z¹, Z² and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a halogen atom, a cyano group, a nitro group, —NR⁶R⁷, or —SR⁸, and R⁶ to R⁸ each independently represent a hydrogen atom or an alkyl group having 1 to 6 carbon atoms, and Z¹ and Z² may be bonded to each other to form a ring,
A³ and A⁴ each independently represent a group selected from the group consisting of —O—, —N(R⁹)—, —S—, and —CO—, and R⁹ represents a hydrogen atom or a substituent,
X represents a hydrogen atom or a non-metal atom of Groups 14 to 16 to which a substituent may be bonded,
D⁵ and D⁶ each independently represent a single bond, —O—CO—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—O—CO—CR³R⁴—, —CR¹R²—CO—O—CR³R⁴—, —NR¹—CR²R³—, or —CO—NR¹—,
R¹, R², R³, and R⁴ each independently represent a hydrogen atom, a fluorine atom, or an alkyl group having 1 to 4 carbon atoms,
SP³ and SP⁴ each independently represent a single bond, an linear or branched alkylene group having 1 to 12 carbon atoms, or a divalent linking group in which one or more —CH₂— groups constituting the linear or branched alkylene group having 1 to 12 carbon atoms are substituted by —O—, —S—, —NH—, —N(Q)-, or —CO—, and Q represents a polymerizable group,
L³ and L⁴ each independently represent a monovalent organic group,
Ax represents an organic group having 2 to 30 carbon atoms, which has at least one aromatic ring selected from the group consisting of an aromatic hydrocarbon ring and an aromatic heterocyclic ring,
Ay represents a hydrogen atom, an alkyl group having 1 to 6 carbon atoms which may have a substituent, or an organic group having 2 to 30 carbon atoms, which has at least one aromatic ring selected from the group consisting of an aromatic hydrocarbon ring and an aromatic heterocyclic ring,
the aromatic rings in Ax and Ay may respectively have a substituent, and Ax and Ay may be bonded to form a ring,
Q³ represents a hydrogen atom or an alkyl group having 1 to 6 carbon atoms which may have a substituent; and
in a case where Ar is a group represented by Formula (Ar-1), Formula (Ar-2), Formula (Ar-4), or Formula (Ar-5), at least one of L¹ or L² represents a polymerizable group, and in a case where Ar is a group represented by Formula (Ar-3), at least one of L³ or L⁴ in Formula (Ar-3) or L¹ or L² in Formula (I) represents a polymerizable group.

3. The organic electroluminescent display device according to claim 2,
wherein at least one of A¹ or A² is a cycloalkylene ring having 6 or more carbon atoms.

4. The organic electroluminescent display device according to claim 1,
wherein the positive A-plate satisfies a following requirement 1A.
0.68≤ReA(450)/ReA(550)≤0.76 Requirement 1A:

5. The organic electroluminescent display device according to claim 1,
wherein the positive A-plate and the positive C-plate satisfy a following requirement 2A.
{ReA(450)/ReA(550)−0.06}≤RthC(450)/RthC(550)/≤{ReA(450)/ReA(550)+0.06} Requirement 2:

6. The organic electroluminescent display device according to claim 1,
wherein ReA(550) of the positive A-plate is 100 to 180 nm.

7. The organic electroluminescent display device according to claim 1,
wherein the positive C-plate exhibits reverse wavelength dispersibility.

8. A phase difference film comprising:
a positive A-plate; and
a positive C-plate,
wherein the positive A-plate exhibits reverse wavelength dispersibility,
the positive A-plate satisfies a following requirement 1,
the positive A-plate and the positive C-plate satisfy a following requirement 2,
0.65≤ReA(450)/ReA(550)≤0.78, and Requirement 1:
{ReA(450)/ReA(550)−0.10}≤RthC(450)/RthC(550)/≤{ReA(450)/ReA(550)+0.10}, Requirement 2:
ReA(450) and ReA(550) represent in-plane retardations of the positive A-plate at wavelengths 450 nm and 550 nm, respectively, and
RthC(450) and RthC(550) represent retardations of the positive C-plate in a thickness direction at wavelengths 450 nm and 550 nm, respectively.

9. The phase difference film according to claim 8,
wherein the positive A-plate is formed by using a liquid crystal compound having a polymerizable group, and
the liquid crystal compound is a compound represented by Formula (I),
L¹-SP¹-A¹-D³-G¹-D¹-Ar-D²-G²-D⁴-A²-SP-L², Formula (I)
in Formula (I), D¹, D², D³ and D⁴ each independently represent a single bond, —O—CO—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—O—CO—CR³R⁴—, —CR¹R²—CO—O—CR³R⁴—, —NR¹—CR²R³—, or —CO—NR¹—,
R¹, R², R³ and R⁴ each independently represent a hydrogen atom, a fluorine atom, or an alkyl group having 1 to 4 carbon atoms,
G¹ and G² each independently represent a divalent alicyclic hydrocarbon group having 5 to 8 carbon atoms, and one or more —CH₂— groups constituting the alicyclic hydrocarbon group may be substituted by —O—, —S— or —NH—,
A¹ and A² each independently represent a single bond, an aromatic ring having 6 or more carbon atoms or a cycloalkylene ring having 6 or more carbon atoms,
SP¹ and SP² each independently represent a single bond, a linear or branched alkylene group having 1 to 14 carbon atoms, or a divalent linking group in which one or more —CH₂— groups constituting the linear or branched alkylene group having 1 to 14 carbon atoms are substituted by —O—, —S—, —NH—, —N(Q)-, or —CO—, and Q represents a polymerizable group,
L¹ and L² each independently represent a monovalent organic group,
Ar represents any aromatic ring selected from the group consisting of groups represented by Formulae (Ar-1) to (Ar-5), 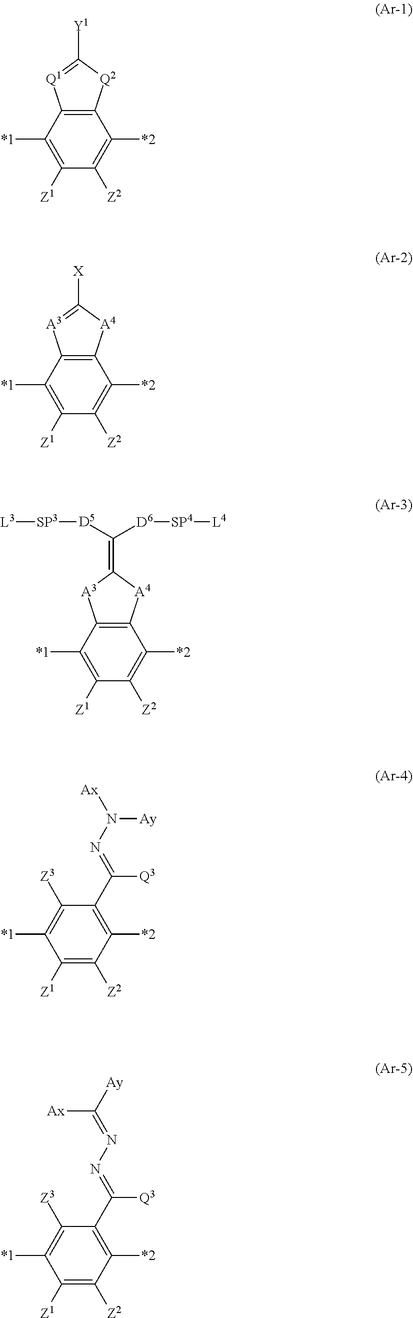
in Formulae (Ar-1) to (Ar-5), *1 represents a bonding position to D¹ and *2 represents a bonding position to D²,
Q¹ represents N or CH,
Q² represents —S—, —O—, or —N(R⁵)— and R⁵ represents a hydrogen atom or an alkyl group having 1 to 6 carbon atoms,
Y¹ represents an aromatic hydrocarbon group having 6 to 12 carbon atoms or an aromatic heterocyclic group having 3 to 12 carbon atoms, which may have a substituent;
Z¹, Z² and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a halogen atom, a cyano group, a nitro group, —NR⁶R⁷, or —SR⁸, and R⁶ to R⁸ each independently represent a hydrogen atom or an alkyl group having 1 to 6 carbon atoms, and Z and Z² may be bonded to each other to form a ring,
A³ and A⁴ each independently represent a group selected from the group consisting of —O—, —N(R⁹)—, —S—, and —CO—, and R⁹ represents a hydrogen atom or a substituent,
X represents a hydrogen atom or a non-metal atom of Groups 14 to 16 to which a substituent may be bonded,
D⁵ and D⁶ each independently represent a single bond, —O—CO—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—O—CO—CR³R⁴—, —CR¹R²—CO—O—CR³R⁴—, —NR¹—CR²R³—, or —CO—NR¹—,
R¹, R², R³, and R⁴ each independently represent a hydrogen atom, a fluorine atom, or an alkyl group having 1 to 4 carbon atoms,
SP³ and SP⁴ each independently represent a single bond, an linear or branched alkylene group having 1 to 12 carbon atoms, or a divalent linking group in which one or more —CH₂— groups constituting the linear or branched alkylene group having 1 to 12 carbon atoms are substituted by —O—, —S—, —NH—, —N(Q)-, or —CO—, and Q represents a polymerizable group,
L³ and L⁴ each independently represent a monovalent organic group,
Ax represents an organic group having 2 to 30 carbon atoms, which has at least one aromatic ring selected from the group consisting of an aromatic hydrocarbon ring and an aromatic heterocyclic ring,
Ay represents a hydrogen atom, an alkyl group having 1 to 6 carbon atoms which may have a substituent, or an organic group having 2 to 30 carbon atoms, which has at least one aromatic ring selected from the group consisting of an aromatic hydrocarbon ring and an aromatic heterocyclic ring,
the aromatic rings in Ax and Ay may respectively have a substituent, and Ax and Ay may be bonded to form a ring,
Q³ represents a hydrogen atom or an alkyl group having 1 to 6 carbon atoms which may have a substituent, and
in a case where Ar is a group represented by Formula (Ar-1), Formula (Ar-2), Formula (Ar-4), or Formula (Ar-5), at least one of L¹ or L² represents a polymerizable group, and in a case where Ar is a group represented by Formula (Ar-3), at least one of L³ or L⁴ in Formula (Ar-3) or L¹ or L²in Formula (I) represents a polymerizable group.

10. The phase difference film according to claim 9,
wherein at least one of A¹ or A² is a cycloalkylene ring having 6 or more carbon atoms.

11. The phase difference film according to claim 8,
wherein the positive A-plate satisfies a following requirement 1A.
0.68≤ReA(450)/ReA(550)≤0.76 Requirement 1A:

12. The phase difference film according to claim 8,
wherein the positive A-plate and the positive C-plate satisfy a following requirement 2A.
{ReA(450)/ReA(550)−0.06}≤RthC(450)/RthC(550)/≤{ReA(450)/ReA(550)+0.06} Requirement 2A:

13. The phase difference film according to claim 8,
wherein ReA(550) of the positive A-plate is 100 to 180 nm.

14. The phase difference film according to claim 8,
wherein the positive C-plate exhibits reverse wavelength dispersibility.

15. A circularly polarizing plate comprising:
a polarizer; and
the phase difference film according to claim 8.

16. The organic electroluminescent display device according to claim 2, wherein the positive A-plate satisfies a following requirement 1A.
0.68≤ReA(450)/ReA(550)≤0.76 Requirement 1A:

17. The organic electroluminescent display device according to claim 3,
wherein the positive A-plate satisfies a following requirement 1A.
0.68≤ReA(450)/ReA(550)≤0.76 Requirement 1A:

18. The organic electroluminescent display device according to claim 2,
wherein the positive A-plate and the positive C-plate satisfy a following requirement 2A.
{ReA(450)/ReA(550)−0.06}≤RthC(450)/RthC(550)/≤{ReA(450)/ReA(550)+0.06} Requirement 2:

19. The organic electroluminescent display device according to claim 3,
wherein the positive A-plate and the positive C-plate satisfy a following requirement 2A.
{ReA(450)/ReA(550)−0.06}<RthC(450)/RthC(550)/≤{ReA(450)/ReA(550)+0.06} Requirement 2:

20. The organic electroluminescent display device according to claim 4,
wherein the positive A-plate and the positive C-plate satisfy a following requirement 2A.
{ReA(450)/ReA(550)−0.06}≤RthC(450)/RthC(550)/≤{ReA(450)/ReA(550)+0.06} Requirement 2:
